(19) United States
(12) Patent Application Publication
(10) Pub. No.: US 2026/0231800 A1
(43) Pub. Date: Aug. 6, 2026

(54) CIRCUIT BOARD, AND SEMICONDUCTOR PACKAGE COMPRISING SAME

(71) Applicant: LG INNOTEK CO., LTD., Seoul (KR)

(72) Inventor: Han Jun CHO, Seoul (KR)

(21) Appl. No.: 19/151,416

(22) PCT Filed: Feb. 1, 2024
(86) PCT No.: PCT/KR2024/001540

§ 371 Date: Jul. 28, 2025

(30) Foreign Application Priority Data
Feb. 1, 2023 (KR) 10-2023-0013719

(51) Int. Cl. H10W 70/685; H10B 80/00; H10D 80/30; H10W 70/05; H10W 70/06; H10W 70/60; H10W 70/65; H10W 70/652; H10W 90/00; H10W 90/10

(52) U.S. Cl. CPC H10W 70/687; H10W 70/06; H10W 70/095; H10W 70/618; H10W 70/652; H10W 70/6565; H10B 80/00; H10D 80/30; H10W 90/10; H10W 90/724

(57) ABSTRACT

A circuit board according to an embodiment includes an insulating layer including a first layer having a first filler, and a second layer disposed on the first layer; a pad part disposed on the insulating layer; and a metal layer disposed on the pad part, wherein the pad part includes a first portion that overlaps the first filler of the first layer of the insulating layer along a horizontal direction and a second portion that does not overlap the first filler of the first layer along the horizontal direction.

### TECHNICAL FIELD

An embodiment relates to a circuit board and a semiconductor package including the same.

### BACKGROUND ART

As performances of electric/electronic products progresses, technologies for disposing a greater number of semiconductor devices on a semiconductor package substrate of a limited size are being proposed and studied. However, since a general semiconductor package is based on mounting a single semiconductor device, there is a limit to obtaining a desired performance.

Accordingly, a semiconductor package that mounts a plurality of semiconductor devices using a plurality of circuit boards has been recently provided. This semiconductor package has a structure in which a plurality of semiconductor devices are connected to each other in a horizontal direction and/or a vertical direction on the circuit board. Accordingly, the semiconductor package has the advantage of efficiently using a mounting area of the semiconductor devices and transmitting high-speed signals through a short signal transmission path between the semiconductor devices.

In addition, semiconductor packages applied to products that provide the Internet of Things (IoT), autonomous vehicles, and high-performance servers are expanding a concept to semiconductor chiplets as a number of semiconductor devices and/or a size of each semiconductor device increases in accordance with a trend of high integration, but a concept is being expanded to semiconductor chiplets where functional parts of a semiconductor device are divided due to limitations of the reticle, etc.

Accordingly, an intercommunication between semiconductor devices and/or semiconductor chiplets is becoming important, and accordingly, there is a trend to dispose an interposer between the circuit board of the semiconductor package and the semiconductor devices.

An interposer can function as a redistribution layer that gradually increases a width or depth of a circuit pattern from the semiconductor device to the semiconductor package in order to facilitate the intercommunication between the semiconductor devices and/or semiconductor chiplets, or to interconnect the semiconductor devices and the semiconductor package circuit board, thereby smoothly transmitting electrical signals between the semiconductor device and the semiconductor package circuit board having a relatively large circuit pattern compared to the circuit pattern of the semiconductor device.

Meanwhile, as a pitch of terminals of the semiconductor device becomes finer, an electrode part provided on the package substrate and/or interposer has a pad part disposed at an uppermost side and protruding above an upper surface of an insulating layer. The pad part may be an electrode electrically connected to the terminal of the semiconductor device.

A manufacturing process of the package substrate and/or interposer may include a process of etching an upper surface of the insulating layer so that the pad part, which is entirely buried within the insulating layer, protrudes above the insulating layer.

At this time, the insulating layer includes a reinforcing member such as a filler, and an upper surface of the insulating layer after etching may have an uneven height by the reinforcing member provided within the insulating layer. For example, the etching of the upper surface of the insulating layer may be performed by a dry method using plasma or a wet method using a chemical agent. A resin of the insulating layer may be removed by a dry method using plasma or a wet method using a chemical agent, but the reinforcing member including SiO2 or TiO2 is not removed. Accordingly, when etching the upper surface of the insulating layer, at least a part of the reinforcing member provided in the insulating layer may be exposed to the upper surface of the insulating layer or may be removed from the insulating layer.

Therefore, the upper surface of the insulating layer after etching includes a first region formed of a resin of the insulating layer removed by etching, a second region formed of an exposed reinforcing member, and a third region of a space where the reinforcing member is removed. At this time, the insulating layer may have different heights in the first to third regions, and due to such height deviation, there may be a problem that a deviation of the adhesion between the insulating layer and the pad part increases, and this problem may deteriorate the reliability of the adhesion between the insulating layer and the pad part.

In addition, when a height of the upper surface of the insulating layer is uneven, a height deviation of the metal layer disposed on the pad part may occur, and this may cause problems such as the semiconductor devices not being stably positioned on the pad.

In addition, when the reinforcing member is exposed on the upper surface of the insulating layer after etching, a metal layer may come into contact with the reinforcing member of the insulating layer, thereby deteriorating the electrical characteristics of the metal layer. For example, a permittivity of the reinforcing member may be higher than a permittivity of the resin of the insulating layer, and there is a problem that a transmission loss of a signal transmitted through the metal layer increases due to the high permittivity of the reinforcing member. In addition, the adhesion between the reinforcing member and the metal layer may be smaller than the adhesion between the reinforcing member and the resin of the insulating layer, and there is a problem that the reliability of the adhesion between the metal layer and the insulating layer is deteriorated.

Therefore, a new method is required that can improve a flatness of the insulating layer while increasing the electrical characteristics of the electrode part and further improving the adhesion between the electrode part and the insulating layer by preventing the reinforcing member from being exposed on the upper surface of the insulating layer after etching.

### DISCLOSURE

### Technical Problem

The embodiment provides a circuit board with improved flatness and a semiconductor package including the same.

In addition, the embodiment provides a circuit board capable of improving adhesion between an insulating layer and an electrode part and a semiconductor package including the same.

In addition, the embodiment provides a circuit board capable of improving electrical characteristics of an electrode part and a semiconductor package including the same.

In addition, the embodiment provides a circuit board capable of minimizing the height deviation of an electrode part and a semiconductor package including the same.

In addition, the embodiment provides a circuit board capable of resolving a problem of large warping in a specific direction and a semiconductor package including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises an insulating layer including a first layer having a first filler, and a second layer disposed on the first layer; a pad part disposed on the insulating layer; and a metal layer disposed on the pad part, wherein the pad part includes a first portion that overlaps the first filler of the first layer of the insulating layer along a horizontal direction and a second portion that does not overlap the first filler of the first layer along the horizontal direction.

In addition, a resin of the first layer of the insulating layer and a resin of the second layer include a same insulating material.

In addition, a resin of the first layer of the insulating layer and a resin of the second layer include different insulating materials.

In addition, the second layer of the insulating layer includes a second filler.

In addition, a diameter of the first filler is same as a diameter of the second filler.

In addition, a content of the first filler in the first layer of the insulating layer is greater than a content of the second filler in the second layer.

In addition, a diameter of the second filler is smaller than a diameter of the first filler.

In addition, the resin of each of the first and second layers includes one of ABF (Ajinomoto Build-up Film), FR-4, BT (Bismaleimide Triazine), and PID (Photo Imageable Dielectric resin).

In addition, the pad part is disposed in a recess provided at an upper surface of the insulating layer.

In addition, the recess has a through hole penetrating the second layer of the insulating layer, and the pad part is disposed in the through hole.

In addition, the recess has a groove part connected to the through hole and provided on an upper surface of the first layer of the insulating layer, and the pad part is disposed in the through hole and the groove part.

In addition, the second portion of the pad part overlaps the second layer of the insulating layer along the horizontal direction.

In addition, the second layer of the insulating layer has a concave-convex part, and the metal layer has a convex part corresponding to the concave-convex part.

In addition, a curvature of the concave-convex part is different from a curvature of the first filler.

In addition, the circuit board further comprises a protective layer disposed on the metal layer, and the second portion of the pad part includes a first region overlapped with the second layer of the insulating layer along the horizontal direction; and a second region provided on the first region and overlapped with the protective layer along the horizontal direction.

In addition, the protective layer has an opening overlapping the metal layer in the vertical direction and penetrating an upper surface and a lower surface of the protective layer.

In addition, a width of the opening in the horizontal direction is smaller than a width of at least one of the pad part and the metal layer in the horizontal direction.

In addition, the second portion of the pad part includes a slope whose width increases toward the first portion.

In addition, the second portion includes a separation portion provided between the slope of the second portion and an inner wall of the through hole of the second layer, and the metal layer is disposed in the separation portion and contacts the slope of the second portion and the inner wall of the through hole of the second layer.

The insulating layer includes a plurality of insulating layers stacked along the vertical direction, and an insulating layer disposed on an uppermost side among the plurality of insulating layers includes the first layer and the second layer, and remaining insulating layers excluding the insulating layer disposed on the uppermost side among the plurality of insulating layers do not include the second layer.

In addition, the circuit board further includes a connection member embedded in the insulating layer.

Meanwhile, a semiconductor package according to an embodiment includes the circuit board described above, a bonding part disposed on a metal layer of the circuit board; and a semiconductor device disposed on the bonding part, wherein the semiconductor device has a first terminal part that overlaps the connection member in a vertical direction; and a second terminal part that does not overlap the connection member in a vertical direction.

### Advantageous Effects

The embodiment can improve a flatness of a circuit board and a semiconductor package including the same, and can stably mount a semiconductor device.

Specifically, the circuit board of the embodiment and the semiconductor package including the same include an insulating layer including a filler, a pad part disposed on the insulating layer, and a metal layer disposed on the pad part. In addition, the pad part includes a first portion that overlaps the filler of the insulating layer along a horizontal direction, and a second portion that does not overlap the filler of the insulating layer along the horizontal direction. At this time, the insulating layer includes a first layer having a reinforcing member and a second layer that does not have a reinforcing member. In addition, the first portion of the pad part overlaps the first layer of the insulating layer along the horizontal direction, and the second portion overlaps the second layer of the insulating layer along the horizontal direction. Accordingly, the embodiment can prevent the reinforcing member from being disposed on the second layer, so that a height of an upper surface of the second layer can be uniform as a whole.

In addition, the embodiment can improve the adhesion between the metal layer and the insulating layer disposed on the pad part.

That is, the upper surface of the insulating layer is positioned lower than an upper surface of the pad part. In addition, the upper surface of the insulating layer is positioned higher than a lower surface of the pad part. That is, at least a part of the pad part is embedded in the insulating layer, and at least the remaining part protrudes above the insulating layer. To this end, the embodiment performs a process of reducing a thickness by etching a partial region of the insulating layer while the upper surface of the insulating layer is positioned at a height higher than the upper surface of the pad part.

At this time, if the reinforcing member is provided in the entire region of the insulating layer, a flatness of the upper surface of the insulating layer may be reduced in the process of etching the insulating layer to reduce the thickness. That is, if the process of etching the insulating layer to reduce the thickness while the reinforcing member is provided in the entire region of the insulating layer is performed, the reinforcing member provided in the insulating layer may be exposed to an upper side of the insulating layer. In addition, if the reinforcing member provided in the insulating layer is exposed to the upper side, the adhesion between the insulating layer and the metal layer described later may be reduced. For example, the adhesion between the reinforcing member and the metal layer may be weaker than the adhesion between the resin of the insulating layer and the metal layer. Due to this, the adhesion between the insulating layer and the metal layer may be reduced, and the metal layer may be peeled off from the insulating layer. In addition, when the metal layer comes into contact with the reinforcing member, a loss of electrical signals and/or power transmitted through the metal layer may occur due to the reinforcing member having a relatively high permittivity.

In addition, when a process of etching the insulating layer to reduce the thickness is performed while the reinforcing member is provided in the entire region of the insulating layer, at least some of the reinforcing members provided in the insulating layer may be removed, and thus a concave part, which is a space where the reinforcing member is removed, may be provided on the upper surface of the insulating layer. At this time, the concave part may have a greater depth than other parts of the upper surface of the insulating layer. Due to this, when the concave part is provided on the upper surface of the insulating layer, a problem may occur in which the metal layer does not completely fill the concave part, and thus a void may be provided between the insulating layer and the metal layer. Furthermore, when a concave part having a relatively large depth is provided on the upper surface of the insulating layer, stress acting on the insulating layer may be concentrated on the concave part, which may deteriorate the physical reliability and/or electrical reliability of the semiconductor package.

In contrast, the insulating layer of the embodiment has a first layer and a second layer. In addition, the first layer of the insulating layer has a resin and a reinforcing member, and the second layer does not have a reinforcing member and includes only a resin. Therefore, the embodiment can prevent the reinforcing member from being exposed on the upper surface of the insulating layer after etching, and thus can allow a height of the upper surface of the insulating layer to be uniform.

Therefore, the embodiment can improve the flatness of the circuit board and the semiconductor package including the same. Furthermore, the metal layer disposed on the pad part does not come into contact with the reinforcing member, and thus the embodiment can improve the electrical characteristics of the metal layer while enhancing the adhesion between the metal layer and the insulating layer.

Furthermore, the embodiment can prevent stress from being concentrated at a specific location on the upper surface of the insulating layer by ensuring that the upper surface of the insulating layer has a uniform height, and further, can evenly distribute the stress to the entire region, thereby improving the physical reliability and electrical reliability of the semiconductor package.

In addition, the embodiment can prevent a bonding part disposed on the metal layer from penetrating into a gap between the metal layer and the insulating layer by improving the adhesion between the metal layer and the insulating layer.

Therefore, the embodiment can suppress the formation of an intermetallic compound (IMC) with poor brittleness between the bonding part and the pad part, thereby improving the physical reliability and electrical reliability of the semiconductor package.

In addition, the embodiment can prevent the semiconductor package from being greatly warped in a specific direction by providing the first layer with the reinforcing member and the second layer without the reinforcing member as the insulating layer, and thus, can stably mount the semiconductor device, and further, can stably operate the semiconductor device.

Specifically, the circuit board and the semiconductor package including the circuit board may be significantly warped in a specific direction. This may occur due to a difference in coefficients of thermal expansion between the insulating layer and the protective layer, a difference in thicknesses of each layer of the insulating layer, a difference in a density of electrode parts provided on a surface of each layer of the insulating layer, a difference in a density of electrode parts provided on a surface of each layer of the insulating layer, and a difference in thicknesses of electrode parts provided on a surface of each layer of the insulating layer. At this time, the embodiment provides a second layer of the insulating layer that does not have a reinforcing member on an uppermost side of a circuit board. The second layer of the insulating layer can have a coefficient of thermal expansion matching function that alleviates a difference in coefficients of thermal expansion between different insulating layers, thereby preventing the circuit board from being significantly warped in a specific direction. For example, the circuit board may be warped downward at both ends in a state where the second layer is not provided on the insulating layer. At this time, the second layer provided on the insulating layer can induce both ends of the circuit board to be warped upward, thereby ultimately allowing the circuit board to maintain a flat state without being warped.

In addition, a concave-convex part is provided on the upper surface of the second layer of the insulating layer. The concave-convex part may be provided on the upper surface of the second layer in a process of etching the second layer of the insulating layer to reduce the thickness of the second layer. At this time, the embodiment forms the concave-convex part by etching the second layer of the insulating layer that does not have the reinforcing member, and accordingly, the reinforcing member may not be exposed through the concave-convex part, and thereby the concave-convex part may have a uniform depth on the upper surface of the second layer. The concave-convex part contacts at least a part of the metal layer disposed on the pad part. Through this, the embodiment can further improve the adhesion between the insulating layer and the metal layer.

At this time, the concave-convex part has a specific curvature. At this time, the curvature of the concave-convex part is different from the curvature of the reinforcing member provided in the first layer of the insulating layer. Here, the different curvature may mean that the reinforcing member is not exposed upwardly through the concave-convex part. Alternatively, the different curvature may mean that the reinforcing member is not removed from the insulating layer during a process of etching the insulating layer to reduce the thickness of the insulating layer, and thus the concave-convex part does not include a portion formed by the removal of the reinforcing member. Through this, the embodiment may improve the physical reliability and/or electrical reliability of the semiconductor package.

### DESCRIPTION OF DRAWINGS

FIG. 1 is a cross-sectional view showing a semiconductor package according to a first embodiment.

FIG. 2 is a drawing showing a semiconductor package including a semiconductor device mounted on the circuit board of FIG. 1.

FIG. 3A is an enlarged view showing a region R1 of FIG. 1 according to a first embodiment.

FIG. 3B is an enlarged view showing a region R1 of FIG. 1 according to a second embodiment.

FIG. 3C is an enlarged view showing a region (R1) of FIG. 1 according to a third embodiment.

FIG. 4 is a cross-sectional view showing a semiconductor package according to a second embodiment.

FIG. 5 is a cross-sectional view showing a semiconductor package according to a third embodiment.

FIG. 6 is a cross-sectional view showing a semiconductor package according to a fourth embodiment.

FIG. 7 is a cross-sectional view showing a partial region of a semiconductor package according to a fifth embodiment.

FIG. 8 is a cross-sectional view showing a partial region of a semiconductor package according to a sixth embodiment.

FIG. 9 is a cross-sectional view showing a semiconductor package according to a seventh embodiment.

FIGS. 10 to 24 are drawings showing a manufacturing method of the semiconductor package shown in FIG. 1 in order of processes.

### BEST MODE

Hereinafter, exemplary embodiments of the present invention will be described in detail with reference to the accompanying drawings, wherein like reference numerals are used to designate identical or similar elements, and redundant description thereof will be omitted. The suffix “module” and “portion” of the components used in the following description are only given or mixed in consideration of ease of preparation of the description, and there is no meaning or role to be distinguished as it is from one another. Also, in the following description of the embodiments of the present invention, a detailed description of related arts will be omitted when it is determined that the gist of the embodiments disclosed herein may be obscured. Also, the accompanying drawings are included to provide a further understanding of the invention, are incorporated in, and constitute a part of this description, and it should be understood that the invention is intended to cover all modifications, equivalents, or alternatives falling within the spirit and scope of the invention.

Terms including ordinals, such as first, second, etc., may be used to describe various components, but the elements are not limited to these terms. The terms are used only for distinguishing one component from another.

When a component is referred to as being “connected” or “contacted” to another component, it may be directly connected or joined to the other component, but it should be understood that other component may be present therebetween. When a component is referred to as being “directly connected” or “directly contacted” to another component, it should be understood that other component may not be present therebetween.

A singular representation includes plural representations, unless the context clearly implies otherwise.

In the present application, terms such as “including” or “having” are used to specify the presence of features, numbers, steps, operations, components, parts, or combinations thereof described in the description. However, it should be understood that the terms do not preclude the presence or addition of one or more other features, numbers, steps, operations, components, parts, or combinations thereof.

Hereinafter, embodiments of a present invention will be described in detail with reference to attached drawings.

### Electronic Device

Before describing the embodiment, an electronic device to which the semiconductor package of the embodiment is applied will be briefly described. The electronic device includes a main board (not shown). The main board may be physically and/or electrically connected to various components. For example, the main board may be connected to the semiconductor package of the embodiment. Various semiconductor devices may be mounted on the semiconductor package.

The semiconductor device may include an active device and/or a passive device. The active device may be a semiconductor chip in the form of an integrated circuit (IC) in which hundreds to millions of devices are integrated in one semiconductor device. The semiconductor device may be a logic chip, a memory chip, or the like. The logic chip may be a central processor (CPU), a graphics processor (GPU), or the like. For example, the logic chip may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far.

The memory chip may be a stack memory such as HBM. The memory chip may also include a memory chip such as volatile memory (e.g., DRAM), non-volatile memory (e.g., ROM), flash memory, and the like.

In addition, the semiconductor device may be an integrated passive device (IPD). In addition, the semiconductor device may be a multilayer ceramic capacitor (MLCC) or a silicon-based capacitor.

On the other hand, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

In addition, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

### Semiconductor Package

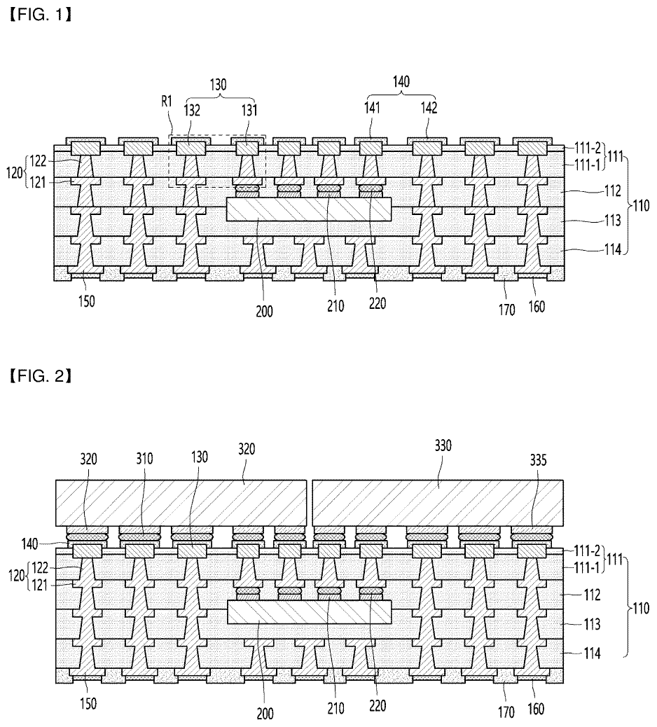

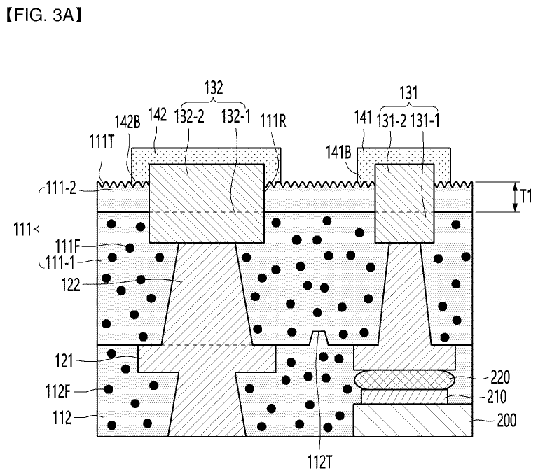

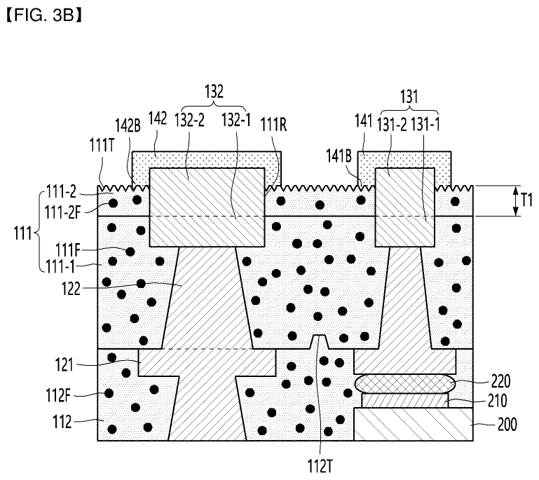

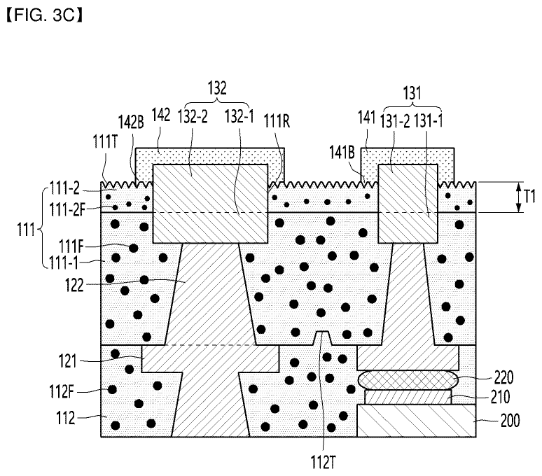

FIG. 1 is a cross-sectional view showing a semiconductor package according to a first embodiment, FIG. 2 is a drawing showing a semiconductor package including a semiconductor device mounted on the circuit board of FIG. 1, FIG. 3a is an enlarged view showing a region R1 of FIG. 1 according to a first embodiment, FIG. 3b is an enlarged view showing a region R1 of FIG. 1 according to a second embodiment, and FIG. 3c is an enlarged view showing a region (R1) of FIG. 1 according to a third embodiment.

Referring to FIGS. 1 to 3c, the semiconductor package includes a circuit board.

In one embodiment, the circuit board means a package substrate. For example, the circuit board is disposed between a main board of the electronic device and the semiconductor device 320 and 330 and can electrically couple them therebetween. The circuit board can horizontally electrically connect the semiconductor devices 320 and 330 and vertically electrically connect the semiconductor devices 320 and 330 and the main board of the electronic device.

In another embodiment, the circuit board means a relay substrate disposed between the package substrate and the semiconductor device 320 and 330. For example, the relay substrate can mean an interposer. That is, the circuit board can horizontally electrically connect the semiconductor devices 320 and 330 and vertically electrically connect the semiconductor devices 320 and 330 and the package substrate.

The semiconductor package includes a semiconductor device 320 and 330 electrically connected on the circuit board.

The semiconductor device 320 and 330 may include a first semiconductor device 320 and a second semiconductor device 330, but is not limited thereto. For example, three or more semiconductor devices may be disposed on the circuit board, or one semiconductor device may be disposed on the circuit board.

The semiconductor package includes a bonding part 310 disposed between the semiconductor device 320 and 330 and the circuit board. The bonding part 310 electrically connects between terminals 325 and 335 of the semiconductor device 320 and 330 and an electrode part (specifically, a metal layer 140) of the circuit board.

The bonding part 310 electrically connects between the electrode part of the circuit board and the terminal 325 and 335 of the semiconductor device 320 and 330 by using at least one bonding method among wire bonding, solder bonding, and direct bonding between metals.

The wire bonding method means electrically connecting the electrode part of the circuit board and the terminal 325 and 335 of the semiconductor device 320 and 330 using a conductor such as gold (Au).

The solder bonding method electrically connects the electrode part of the circuit board and the terminal 325 and 335 of the semiconductor device 320 and 330 using a material containing at least one of Sn, Ag, and Cu.

The direct metal bonding method means applying heat and pressure between the electrode part of the circuit board and the terminal 325 and 335 of the semiconductor device 320 and 330 to recrystallize without the use of solder, wire, conductive adhesive, etc., thereby directly bonding the electrode part of the circuit board and the terminal 325 and 335 of the semiconductor device 320 and 330. In this case, the bonding part 310 may mean a metal layer formed between the electrode part of the circuit board and the terminal 325 and 335 of the semiconductor device 320 and 330 by recrystallization.

For example, the bonding part 310 may electrically connect the electrode part of the circuit board and the terminal 325 and 335 of the semiconductor device 320 and 330 by a thermal compression bonding method. The thermal compression bonding method may reduce a volume of the bonding part 310 and prevent short circuits between multiple bonding parts. Therefore, when the terminal 325 and 335 of the semiconductor device 320 and 330 and/or the electrode part of the circuit board have a fine pitch, the thermal compression bonding method may be advantageous.

According to one embodiment, the semiconductor package includes a connection member 200 embedded in the circuit board.

The connection member 200 is partially overlapped with the semiconductor devices 320 and 330 disposed on the circuit board in a vertical direction.

The connection member 200 electrically connects a part of the terminal 325 of the first semiconductor device 320 and a part of the terminal 335 of the second semiconductor device 330.

A semiconductor device may be mounted on a circuit board as a functionally separated chiplet unit, or multiple semiconductor devices having different functions, such as a CPU and GPU, or a GPU and HBM, and a connection member 200 may perform the function of horizontally electrically connecting them.

In one embodiment, the connection member 200 is an inorganic bridge. For example, the inorganic bridge may be a silicon bridge. For example, the connection member 200 may include a silicon substrate and a redistribution layer.

In another embodiment, the connection member 200 is an organic bridge. For example, the connection member 200 may include an organic material. For example, the connection member 200 may include an organic substrate in which the silicon substrate of the inorganic bridge is redisposed with an organic substrate.

The connection member 200 includes a connection pad 210. The connection pad 210 of the connection member 200 is electrically connected to the electrode part of the circuit board. In addition, the electrode part of the circuit board is electrically connected to the terminal 325 and 335 of the semiconductor device 320 and 330. Therefore, the connection member 200 electrically connects the terminals 325 and 335 of the semiconductor device 320 and 330.

In addition, a bonding member 220 is disposed between the connection member 200 and the electrode part 120 of the substrate. The bonding member 220 is provided between the connection pad 210 of the connection member 200 and the electrode part 120. The bonding member 220 can electrically connect the connection pad 210 of the connection member 200 by fixing the connection pad on the electrode part 120.

The circuit board electrically connected to the connection member 200 and the semiconductor device 320 and 330 is specifically described as follows.

The circuit board includes an insulating layer 110. The insulating layer 110 may include an organic material that does not include a reinforcing member, which has excellent processability, enables slimming of the circuit board, and enables miniaturization of the electrode part 120 provided on the circuit board. For example, the insulating layer 110 of the circuit board may use ABF (Ajinomoto Build-up Film), a product released by Ajinomoto Co., Ltd., and FR-4, BT (Bismaleimide Triazine), PID (Photo Image-able Dielectric resin), etc. may be used.

The insulating layer 110 may be provided in a form in which a plurality of are laminated. For example, as shown in FIG. 1, the insulating layer 110 may include first to fourth insulating layers 111, 112, 113, and 114, but is not limited thereto. For example, the insulating layer 110 may be provided with three or fewer insulating layers, or may be provided with five or more insulating layers.

In one embodiment, a plurality of layers of the insulating layer 110 may be provided with a same insulating material, but is not limited thereto, and at least one layer among a plurality of layers of the insulating layer 110 may be provided with an insulating material different from at least other layers.

When the insulating layer 110 is provided with a plurality of layers, interfaces between the plurality of layers may not be easily distinguished. In this case, the distinction of the interfaces between the layers may be made by an electrode part 120 disposed in the insulating layer 110. The electrode part 120 includes a first electrode part 121 and a second electrode part 122. The first electrode part 121 is disposed at an interface between the plurality of layers of the insulating layer 110. The first electrode part 121 may include a pad and/or a trace, and may be referred to as a wiring electrode part. The second electrode part 122 may be referred to as a via electrode part or a through electrode part. The second electrode part 122 electrically connects the first electrode parts 121 disposed in different layers along a vertical direction. At this time, a width of the first electrode part 121 in the horizontal direction is different from a width of the second electrode part 122 in the horizontal direction. Therefore, a difference between the width of the first electrode part 121 and the width of the second electrode part 122 in the horizontal direction can be used to distinguish interfaces of a plurality of layers of the insulating layer 110. In addition, a slope of a side surface of the first electrode part 121 is different from a slope of a side surface of the second electrode part 122. Therefore, a difference between the slope of the side surface of the first electrode part 121 and the slope of the side surface of the second electrode part 122 can be used to distinguish interfaces of a plurality of layers of the insulating layer 110.

However, even if a plurality of layers of the insulating layer 110 include a same insulating material, the interfaces between them can be distinguished.

Through a laminated structure of the above-described insulating layer 110, the circuit board of the embodiment can electrically connect between the semiconductor device 320 and 330 and the package substrate and/or the main board.

The insulating layer 110 includes a resin and a reinforcing member provided in the resin. For example, each of the first to fourth insulating layers 111, 112, 113, and 114 includes a resin and a reinforcing member. Here, the reinforcing member may mean a filler and may be distinguished from glass fiber. The reinforcing member may mean a filler having a predetermined diameter. The reinforcing member may be disposed to have an arbitrary size and be dispersed in each of the first to fourth insulating layers 111, 112, 113, and 114.

At this time, the reinforcing member provided in at least one layer among the first to fourth insulating layers 111, 112, 113, and 114 may have a different arrangement structure from the reinforcing member provided in at least another layer. Here, the arrangement structure may mean an arrangement position of the reinforcing member provided in the insulating layer. Therefore, the different arrangement structure may mean that the arrangement position of the reinforcing member provided in at least one insulating layer is different from the arrangement position of the reinforcing member provided in at least another insulating layer.

For example, the reinforcing member provided in at least one layer among the first to fourth insulating layers 111, 112, 113, and 114 may be disposed in some region excluding a specific region in the entire region in a thickness direction of a corresponding insulating layer, and the reinforcing member provided in at least one other layer may be disposed to be distributed in an entire region in the thickness direction of a corresponding insulating layer.

Specifically, the arrangement structure of the reinforcing member provided in the first insulating layer 111 disposed on an uppermost side of the semiconductor package among the first to fourth insulating layers 111, 112, 113, and 114 may be different from the arrangement structure of the reinforcing member provided in the second to fourth insulating layers 112, 113, and 114.

That is, the reinforcing member provided in the first insulating layer 111 may be provided in some regions among the entire region in the thickness direction of the first insulating layer 111. For example, the first insulating layer 111 may be divided into a first layer 111-1 and a second layer 111-2 on the first layer 111-1. The first layer 111-1 of the first insulating layer 111 may be a lower region of the first insulating layer 111, and the second layer 111-2 of the first insulating layer 111 may be an upper region of the first insulating layer 111 excluding the first layer 111-1. Here, the first layer 111-1 and the second layer 111-2 of the first insulating layer 111 may be a region that is provided with a reinforcing member and a region that is not provided with a reinforcing member along a thickness direction of a single insulating layer, or may mean a plurality of layers including a layer that is provided with a reinforcing member and a layer that is not provided with a reinforcing member.

The first layer 111-1 of the first insulating layer 111 includes a resin and a reinforcing member 111F provided in the resin. For example, the reinforcing member 111F is disposed to be dispersed over the entire region of the resin of the first layer 111-1 of the first insulating layer 111. In addition, the second layer 111-2 of the first insulating layer 111 does not have the reinforcing member. For example, the second layer 111-2 of the first insulating layer 111 may only have a resin, and thus may be referred to as a non-filler resin layer. Here, the non-filler resin layer may mean a layer that does not have a reinforcing member such as a filler, but is not limited thereto. For example, the non-filler resin layer may mean a layer having a reinforcing member having a size smaller than that of the reinforcing member of the first layer 111-1 of the first insulating layer 111, or may mean a layer having a reinforcing member having a content smaller than that of the reinforcing member of the first layer 111-1 of the first insulating layer 111. The second layer 111-2 of the first insulating layer 111 may be freely used within a range where problems such as peeling do not occur by controlling a difference in the coefficient of thermal expansion rate with respect to the first layer 111-1 of the first insulating layer 111 according to a technical idea of a present invention.

Referring to FIGS. 3a to 3c, the second layer 111-2 of the first insulating layer 111 may have a reinforcing member, or may not have a reinforcing member.

Referring to FIG. 3a, the first layer 111-1 of the first insulating layer 111 may have a reinforcing member 111F, and the second layer 111-2 of the first insulating layer 111 may not have a reinforcing member.

In this case, the non-filler resin layer provided as the second layer 111-2 of the first insulating layer 111 may mean a layer that does not have a reinforcing member. Therefore, according to one embodiment, by using the second layer 111-2 of the first insulating layer 111 that does not have a reinforcing member, a reinforcing member such as a filler may not be exposed to an upper side of the first insulating layer 111, thereby improving the adhesion between a plurality of insulating layers and minimizing the electrical loss of the electrode part.

Referring to FIG. 3b, the first layer 111-1 of the first insulating layer 111 may have a first reinforcing member 111F such as a first filler. The second layer 111-2 of the first insulating layer 111 may have a second reinforcing member 111-2F such as a second filler. At this time, a diameter of the first reinforcing member 111F may be the same as a diameter of the second reinforcing member 111-2F. In this case, a content of the second reinforcing member 111-2F in the second layer 111-2 of the first insulating layer 111 may be smaller than a content of the first reinforcing member 111F in the first layer 111-1. Accordingly, according to another embodiment, by using the second layer 111-2 of the first insulating layer 111 having a relatively small content of the second reinforcing member 111-2F, the reinforcing member, such as a filler, can be prevented from being exposed to the upper side of the first insulating layer 111, thereby improving the adhesion between a plurality of insulating layers and minimizing the electrical loss of the electrode part.

Referring to FIG. 3c, the first layer 111-1 of the first insulating layer 111 may have a first reinforcing member 111F such as a first filler. The second layer 111-2 of the first insulating layer 111 may have a second reinforcing member 111-2F such as a second filler. At this time, a diameter of the first reinforcing member 111F may be different from a diameter of the second reinforcing member 111-2F. Preferably, at this time, the diameter of the first reinforcing member 111F may be larger than the diameter of the second reinforcing member 111-2F. In addition, a content of the second reinforcing member 111-2F in the second layer 111-2 of the first insulating layer 111 may be smaller than a content of the first reinforcing member 111F in the first layer 111-1. Therefore, according to another embodiment, by using the second layer 111-2 of the first insulating layer 111 having the second reinforcing member 111-2F having a relatively small diameter, the reinforcing member, such as a filler, may not be exposed to the upper side of the first insulating layer 111, thereby improving the adhesion between the plurality of insulating layers and minimizing the electrical loss of the electrode part. For the convenience of explanation, it will be explained below that the second layer 111-2 of the first insulating layer 111 does not have a reinforcing member.

Accordingly, the first insulating layer 111 includes a first layer 111-1 having a reinforcing member 111F and a second layer 111-2 not having a reinforcing member. Through this, the embodiment can improve a flatness of the semiconductor package and enable the semiconductor device to be stably mounted.

For example, the embodiment can allow the second layer 111-2 of the first insulating layer 111 to not have a reinforcing member, so that a height of an upper surface of the second layer 111-2 can be uniform as a whole. In addition, the embodiment can improve the adhesion with the metal layer 140 disposed on the first insulating layer 111. In addition, the embodiment can prevent the semiconductor package from being greatly warped in a specific direction. In addition, the embodiment can improve the physical reliability and/or electrical reliability of the semiconductor package. In addition, as described above, a fact that the second layer 111-2 of the first insulating layer 111 does not have a reinforcing member may mean that a reinforcing member having a relatively small content and/or a reinforcing member having a relatively small diameter may be provided.

An upper surface of the first insulating layer 111 is positioned lower than an upper surface of the pad part 130 described below. In addition, the upper surface of the first insulating layer 111 is positioned higher than a lower surface of the pad part 130. That is, at least a part of the pad part 130 is embedded in the first insulating layer 111, and at least the remaining part of the pad part 130 protrudes above the first insulating layer 111. To this end, the embodiment performs a process of etching a portion of the first insulating layer 111 to reduce the thickness of the first insulating layer while the upper surface of the first insulating layer 111 is positioned at a height higher than the upper surface of the pad part 130.

At this time, if the reinforcing member 111F is provided in the entire region of the first insulating layer 111, a flatness of the upper surface of the first insulating layer 111 may deteriorate in a process of etching the first insulating layer 111 to reduce the thickness of the first insulating layer. That is, if the process of etching the first insulating layer 111 to reduce the thickness of the first insulating layer is performed in a state where the reinforcing member 111F is provided in the entire region of the first insulating layer 111, the reinforcing member provided in the first insulating layer 111 may be exposed to an upper side of the first insulating layer 111. In addition, if the reinforcing member 111F provided in the first insulating layer 111 is exposed to the upper side, the adhesion between the insulating layer 110 and a metal layer 140 described later may deteriorate. For example, the adhesion between the reinforcing member 111F and the metal layer 140 may be weaker than the adhesion between the resin of the insulating layer 110 and the metal layer 140. As a result, the adhesion between the insulating layer 110 and the metal layer 140 may be reduced, and the metal layer 140 may be peeled off from the insulating layer 110. In addition, if the metal layer 140 comes into contact with the reinforcing member 111F, a loss of electrical signals and/or power transmitted through the metal layer 140 may occur due to the reinforcing member 111F having a relatively high permittivity.

In addition, when a process of etching the first insulating layer 111 to reduce the thickness of the first insulating layer is performed while the reinforcing member 111F is provided in the entire region of the first insulating layer 111, at least a part of the reinforcing members provided in the first insulating layer 111 may be removed, and thus a concave part, which is a space where the reinforcing member is removed, may be provided on the upper surface of the first insulating layer 111. At this time, the concave part may have a greater depth than other parts of the upper surface of the first insulating layer 111. Due to this, if the concave part is provided on the upper surface of the first insulating layer 111, a problem may occur in which the metal layer 140 does not completely fill the concave part, and thus a void may be provided between the first insulating layer 111 and the metal layer 140. Furthermore, if a concave part is provided on the upper surface of the first insulating layer 111, stress acting on the insulating layer 110 may be concentrated on the concave part, which may deteriorate the physical reliability and/or electrical reliability of the semiconductor package.

In contrast, the first insulating layer 111 of the embodiment has a first layer 111-1 and a second layer 111-2. The first layer 111-1 of the first insulating layer 111 has a resin and a reinforcing member 111F, and the second layer 111-2 does not have a reinforcing member.

Therefore, the embodiment can prevent the reinforcing member 111F from being exposed on the upper surface of the first insulating layer 111 after etching, and accordingly, a height of the upper surface of the first insulating layer 111 can be made uniform.

Therefore, the embodiment can improve the flatness of the semiconductor package. Furthermore, the embodiment can improve the electrical characteristics of the metal layer 140 while improving the adhesion between the metal layer 140 and the insulating layer 110 by not allowing the metal layer 140 disposed on the pad part 130 to come into contact with the reinforcing member 111F, thereby improving the adhesion between the metal layer 140 and the insulating layer 110.

Furthermore, the embodiment can prevent stress from being concentrated at a specific location on the upper surface of the first insulating layer 111 by making the upper surface of the first insulating layer 111 have a uniform height, and further, can evenly distribute the stress to the entire region, thereby improving the physical reliability and electrical reliability of the semiconductor package.

In addition, the embodiment can prevent the bonding part 310 disposed on the metal layer 140 from penetrating or diffusing into a gap between the metal layer 140 and the insulating layer 110 by improving the adhesion between the metal layer 140 and the insulating layer 110.

Therefore, the embodiment can suppress the formation of an intermetallic compound (IMC) having poor brittleness between the bonding part 310 and the pad part 130, and can improve the physical reliability and electrical reliability of the semiconductor package accordingly.

In addition, the embodiment can prevent the semiconductor package from being greatly warped in a specific direction by providing the first insulating layer 111 with the first layer 111-1 having the reinforcing member 111F and the second layer 111-2 not having the reinforcing member, so that the semiconductor package is advantageous in warpage control, and thus the semiconductor device can be stably mounted, but further, the semiconductor device can be stably operated.

Specifically, if the first insulating layer 111 has the first layer 111-1 excluding the second layer 111-2, the semiconductor package may be significantly warped in a specific direction. This may occur due to a difference in coefficients of thermal expansion between the insulating layer 110 and the protective layer 170, a difference in the thickness of each layer of the insulating layer 110, a difference in the density of the electrode part 120 provided on the surface of each layer of the insulating layer 110, and a difference in the thickness of the electrode part 120 provided on the surface of each layer of the insulating layer 110. At this time, the embodiment is such that the second layer 111-2 of the first insulating layer 111 that does not have a reinforcing member is provided on the uppermost side of the circuit board. At this time, the coefficient of thermal expansion of the second layer 111-2 of the first insulating layer 111 is different from the coefficients of thermal expansion of each of the first layer 111-1 of the first insulating layer 111, the second insulating layer 112, the third insulating layer 113, the fourth insulating layer 114 and the protective layer 170. For example, the second layer 111-2 of the first insulating layer 111 can function as a buffer layer that alleviates the difference in coefficients of thermal expansion between the multiple layers of the insulating layer 110 and the protective layer 170. Therefore, the second layer 111-2 of the first insulating layer 111 can have a coefficient of thermal expansion matching function that alleviates the difference in thermal expansion coefficients between the insulating layer 110 and the protective layer 170, thereby preventing the circuit board from being significantly warped in a specific direction. For example, the circuit board may have both ends bent downward in a state where the second layer 111-2 is not provided on the first insulating layer 111. At this time, the second layer 111-2 provided on the first insulating layer 111 may induce both ends of the circuit board to bend upward, thereby ultimately allowing the circuit board to maintain a flat state without being bent. In addition, the embodiment may easily control the warpage of the circuit board by adjusting the thickness of the second layer 111-2 of the first insulating layer 111, thereby enabling the embodiment to improve the physical reliability and/or electrical reliability of the semiconductor package.

In addition, referring to FIGS. 3a to 3c, a concave-convex part 111T is provided on the upper surface of the second layer 111-2 of the first insulating layer 111. The concave-convex part 111T may be provided on the upper surface of the second layer 111-2 in a process of reducing the thickness by etching the second layer 111-2 of the first insulating layer 111. At this time, the embodiment forms the concave-convex part 111T by etching the second layer 111-2 of the first insulating layer 111 that does not have a reinforcing member, and accordingly, the reinforcing member may not be exposed through the concave-convex part 111T, and through this, the concave-convex part 111T may be provided on the upper surface of the second layer 111-2 with a uniform depth. The concave-convex part 111T is in contact with at least a part of the metal layer 140 disposed on the pad part 130. Through this, the embodiment can further improve the adhesion between the first insulating layer 111 and the metal layer 140.

The concave-convex part 111T has a specific curvature. At this time, a curvature of the concave-convex part 111T is different from a curvature of the reinforcing member 111F provided in the first layer 111-1 of the first insulating layer 111. Here, the different curvature may mean that the reinforcing member 111F is not exposed upward through the concave-convex part 111T. Alternatively, the different curvature may mean that the reinforcing member 111F is not separated from the first insulating layer 111 in the process of etching the first insulating layer 111 to reduce the thickness, and thus the concave-convex part 111T does not include the concave part formed by separation of the reinforcing member 111F. Through this, the embodiment may improve the physical reliability and/or electrical reliability of the semiconductor package.

The second layer 111-2 of the first insulating layer 111 is provided with a predetermined thickness T1. The thickness T1 of the second layer 111-2 of the first insulating layer 111 may mean a vertical distance from the upper surface of the second layer 111-2 to the lower surface of the second layer 111-2, but is not limited thereto. For example, the thickness T1 of the second layer 111-2 may mean the vertical distance from a bottom surface of the concave-convex part 111T to a lower surface of the second layer 111-2.

At this time, the thickness T1 of the second layer 111-2 has a range of 1 um to 5.5 μm. For example, the thickness T1 of the second layer 111-2 has a range of 1.5 μm to 5.0 μm. For example, the thickness T1 of the second layer 111-2 has a range of 1.5 μm to 4.5 μm. If the thickness T1 of the second layer 111-2 is less than 1 μm, an effect that occurs due to the absence of the reinforcing member in the first insulating layer 111 may be minimal. For example, if the thickness T1 of the second layer 111-2 is less than 1 μm, the effect of improving the flatness of the semiconductor package, the effect of improving the adhesion between the insulating layer and the metal layer, the effect of preventing warpage of the semiconductor package, or the effect of suppressing the formation of intermetallic compounds may be insufficient. In addition, if the thickness T1 of the second layer 111-2 is less than 1 μm, at least a part of the reinforcing member 111F provided in the first region 111-2 of the first insulating layer 111 may be exposed upward due to process deviation in the process of etching the first insulating layer 111. In addition, if the thickness T1 of the second layer 111-2 exceeds 5.5 μm, a content of the reinforcing member provided in the first insulating layer 111 may decrease, and thus the rigidity of the circuit board may deteriorate. In addition, if the thickness of the first layer 111-1 of the first insulating layer 111 is increased to prevent the rigidity of the circuit board from being reduced, the thickness of the semiconductor package may increase, and miniaturization of the semiconductor package may be difficult accordingly.

At this time, the first insulating layer 111 in one embodiment is provided as a single layer. For example, the first layer 111-1 and the second layer 111-2 of the first insulating layer 111 are provided as a single layer, and in the embodiment, the reinforcing member 111F may be provided only in the first layer 111-1 excluding the second layer 111-2 within the first insulating layer 111 of the single layer. For example, in the embodiment, a metal member having a protrusion can be pressed onto a second layer 111-2 of the first insulating layer 111 while reinforcing members 111F are disposed in both the first layer 111-1 and the second layer 111-2 of the first insulating layer 111, thereby causing the reinforcing member 111F disposed in the second layer 111-2 of the first insulating layer 111 to move to the first layer 111-1 of the first insulating layer 111. Accordingly, the first insulating layer 111 of the first insulating layer 111 can be provided with a reinforcing member 111F, and the second layer 111-2 cannot be provided with a reinforcing member. At this time, a resin of the first layer 111-1 of the first insulating layer 111 and a resin of the second layer 111-2 are provided with a same material, and accordingly, an interface between the first layer 111-1 and the second layer 111-2 may not be distinguished.

In another embodiment, the first insulating layer 111 is provided with a plurality of layers. For example, the first insulating layer 111 may have a form in which the first layer 111-1 and the second layer 111-2 are joined. For example, the first insulating layer 111 may have a first layer 111-1 provided with a reinforcing member, and a second layer 111-2 not provided with a reinforcing member laminated on the first layer 111-1. At this time, a resin of the first layer 111-1 and a resin of the second layer 111-2 may contain the same insulating material, in which case, the interface between the first layer 111-1 and the second layer 111-2 may not be distinguished. In contrast, even if the resin of the first layer 111-1 and the resin of the second layer 111-2 contain the same insulating material, the interface between the first layer 111-1 and the second layer 111-2 may be distinguished due to the difference in molecular weight at a bonding interface during a bonding process. In addition, the resin of the first layer 111-1 and the resin of the second layer 111-2 may contain different insulating materials, in which case, the interface between the first layer 111-1 and the second layer 111-2 may be distinguished.

At this time, the resin of the first layer 111-1 of the first insulating layer 111 and the resin of the second layer 111-2 may include any one of a thermosetting resin, a thermoplastic resin, or a photocurable resin, and for example, may be any one of polyimide (PI), polyethylene terephthalate (PET), propylene glycol, polycarbonate (PC), COC (Cyclic Olefin Copolymer), COP (Cyclic Olefin Polymer), photoisotropic polycarbonate (PC), photoisotropic polymethyl methacrylate (PMMA), ABF (Ajinomoto Build-up Film), FR-4, BT (Bismaleimide Triazine), and PID (Photo Imageable Dielectric resin).

In addition, each of the second insulating layer 112, the third insulating layer 113, and the fourth insulating layer 114, excluding the first insulating layer 111, may be provided with a reinforcing member in the entire region in the thickness direction, thereby improving the rigidity of the circuit board.

In addition, referring to FIGS. 3a to 3c, a convex part 112T that is convex toward the upper surface of the first insulating layer 111 is provided at an interface between the first insulating layer 111 and the second insulating layer 112. For example, a concave surface that is concave toward the upper surface of the first insulating layer 111 may be provided on a lower surface of the first insulating layer 111, and a convex surface corresponding to the concave surface of the first insulating layer 111 may be provided on an upper surface of the second insulating layer 112. This can form a groove with a certain depth on the lower surface of the first insulating layer 111, and the second insulating layer 112 can fill the groove formed on the lower surface of the first insulating layer 111, and thus, a convex part 112T can be provided on the upper surface of the second insulating layer 112.

The convex part 112T does not overlap with the connection member 200 in the vertical direction at the interface between the first insulating layer 111 and the second insulating layer 112. For example, the interface between the first insulating layer 111 and the second insulating layer 112 includes an overlapping region that overlaps with the connection member 200 in the vertical direction. In addition, the convex part 112T can be provided at a position spaced apart from the overlapping region by a certain distance in the horizontal direction. The convex part 112T can have a closed loop shape surrounding a periphery of the overlapping region, but is not limited thereto. For example, the convex part 112T may be provided with a plurality of convex patterns spaced apart from each other around the overlapping region. The convex part 112T may function as an alignment pit to align the connection pad 210 of the electrode part 120 and the connection member 200 while guiding a position where the connection member 200 is to be attached in a manufacturing process of the semiconductor package. For example, the connection member 200 may be attached on the electrode part 120 with the connection pad 210 facing downward, and this may make it difficult to accurately align the connection pad 210 of the connection member 200 and the electrode part 120. Therefore, the embodiment can be provided with a convex part 112T corresponding to the alignment fit corresponding to the position where the connection member 200 is to be attached, thereby improving the alignment between the connection pad 210 of the connection member 200 and the electrode part 120.

In addition, the circuit board includes an electrode part 120 disposed on an insulating layer 110. The electrode part 120 includes a first electrode part 121 and a second electrode part 122 that are distinguished according to position and function.

The first electrode part 121 can be disposed horizontally between each of the plurality of layers of the insulating layer 110, and the second electrode part 122 can be disposed vertically while penetrating each of the plurality of layers of the insulating layer 110.

The electrode part 120 is distinguished into a plurality of groups. The electrode part 120 includes a first group of electrode parts that overlap with the semiconductor device 320 and 330 and the connection member 200 in the vertical direction. In addition, the electrode part 120 includes a second group of electrode parts that overlap with the first group of electrode parts in the horizontal direction and do not overlap with the connection member 200 in the vertical direction. The first group of electrode parts overlap with the semiconductor device 320 and 330 in the vertical direction. That is, the second group of electrode parts is an electrode part that overlaps with the connection member 200 and the semiconductor device 320 and 330 in the vertical direction, respectively, and the first group of electrode parts is an electrode part that does not overlap with the connection member 200 in the vertical direction but overlaps with the semiconductor device 320 and 330 in the vertical direction.

At least one of a width of the first electrode part, a width of the second electrode part, and a spacing between the plurality of first electrode parts spaced apart in the horizontal direction in the electrode parts of the first group may be different from a width of the first electrode part, a width of the second electrode part, and a spacing between the plurality of first electrode parts spaced apart in the horizontal direction in the electrode parts of the second group. For example, at least one of a width of the first electrode part, a width of the second electrode part, and a spacing between the plurality of first electrode parts spaced apart in the horizontal direction in the electrode parts of the first group may be smaller than a width of the first electrode part, a width of the second electrode part, and a spacing between the plurality of first electrode parts spaced apart in the horizontal direction in the electrode parts of the second group.

Through this, the embodiment can arrange both the first electrode part and the second electrode part of the electrode part of the first group within a limited space, and can stably electrically connect the semiconductor device 320 and 330 and the connection member 200.

The first electrode part 120 includes a pad part 130 disposed on an uppermost side of the circuit board. The pad part 130 is provided on the first insulating layer 111. The pad part 130 is connected to a terminal of a semiconductor device, and thus may be referred to as a bump. In addition, the first electrode part 120 further includes a lower pad part 150 disposed on a lowest side of the circuit board. The lower pad part 150 may function as a terminal connected to an external substrate (e.g., a package substrate or a main board).

The pad part 130 is disposed in a recess 111R provided on the upper surface of the first insulating layer 111. The recess 111R penetrates the second layer 111-2 of the first insulating layer 111. Accordingly, the recess 111R includes a through hole (111R1, see FIG. 4) penetrating the second layer 111-2 of the first insulating layer 111. In addition, the recess 111R is provided concavely on the upper surface of the first layer 111-1 of the first insulating layer 111. Accordingly, the recess 111R has a groove part (111R2, see FIG. 4) concavely provided on the upper surface of the first layer 111-1 of the first insulating layer 111 and a through hole 111R1 penetrating the second layer 111-2 of the first insulating layer 111. Accordingly, the pad part 130 is provided penetrating the second layer 111-2 of the first insulating layer 111.

The pad part 130 can be divided into a plurality of parts along the vertical direction. For example, the pad part 130 has a first portion that overlaps the reinforcing member of the insulating layer 110 along the horizontal direction, and a second portion that is provided on the first portion and does not overlap the reinforcing member of the insulating layer 110 along the horizontal direction. Specifically, the pad part 130 includes a plurality of first pads 131 that overlap the connection member 200 along the vertical direction, and a plurality of second pads 132 that overlap the first pad 131 along the horizontal direction and do not overlap the connection member 200 along the vertical direction. Each of the plurality of first pads 131 and the plurality of second pads 132 of the pad part 130 is disposed in a recess 111R provided on the upper surface of the first insulating layer 111.

In addition, the plurality of first pads 131 include a first portion 131-1 that overlaps with the reinforcing member of the insulating layer 110 along the horizontal direction, and a second portion 131-2 that does not overlap with the reinforcing member of the insulating layer 110 along the horizontal direction. In addition, the plurality of second pads 132 include a first portion 132-1 that overlaps with the reinforcing member of the insulating layer 110 along the horizontal direction, and a second portion 132-2 that does not overlap with the reinforcing member of the insulating layer 110 along the horizontal direction. At this time, the second portions 131-2 and 132-2 of each of the plurality of first pads 131 and the plurality of second pads 132 overlap with the insulating layer 110 along the horizontal direction, but do not overlap with the reinforcing member of the insulating layer 110 along the horizontal direction. That is, the second portion 131-2 and 132-2 of each of the plurality of first pads 131 and the plurality of second pads 132 overlaps the second layer 111-2 of the first insulating layer 111 along the horizontal direction, and thus does not overlap the reinforcing member 111F provided in the first insulating layer 111 along the horizontal direction. Through this, the embodiment can improve a flatness of the semiconductor package and enable the semiconductor device to be stably attached. That is, by preventing the second portions 131-2 and 132-2 of each of the plurality of first pads 131 and the plurality of second pads 132 from overlapping with the reinforcing member of the insulating layer 110 along the horizontal direction, the flatness of the metal layer 140 disposed on the first pad 131 and the second pad 132 can be improved, and further, the adhesion between the metal layer 140 and the insulating layer 110 and the adhesion between the metal layer 140 and the pad part 130 can be improved. Furthermore, the embodiment can minimize stress due to thermal stress transmitted to the second portions 131-2 and 132-2 of each of the plurality of first pads 131 and the plurality of second pads 132, and thereby improve the physical reliability and/or electrical reliability of the plurality of first pads 131 and the plurality of second pads 132.

In addition, each of the plurality of first pads 131 overlaps with the connection member 200 in the vertical direction, and each of the plurality of second pads 132 does not overlap with the connection member 200 in the vertical direction, and thus, they have different widths in the horizontal direction. For example, a width of each of the plurality of first pads 131 in the horizontal direction may be smaller than a width of each of the plurality of second pads 132 in the horizontal direction. Through this, the embodiment can improve the circuit integration of the pad part 130, and thus reduce a length of an electrode line connected to the semiconductor device. Therefore, the embodiment can improve the signal transmission characteristics by minimizing the signal transmission loss, and further reduce a volume of the semiconductor package.

In addition, the upper surfaces of each of the plurality of first pads 131 and the plurality of second pads 132 of the embodiment are located on a same plane. Through this, the embodiment can allow the semiconductor device to be stably coupled to the plurality of first pads 131 and the plurality of second pads 132.

In addition, the circuit board includes a metal layer 140 disposed on the pad part 130. The metal layer 140 may be provided on the upper surface and side surface of the pad part 130. A lower surface of the metal layer 140 contacts the upper surface of the second layer 111-2 of the first insulating layer 111. At this time, a concave-convex part 111T is provided on the upper surface of the second layer 111-2, and accordingly, the metal layer 140 may have a convex part corresponding to the concave-convex part 111T.

Specifically, the metal layer 140 includes a plurality of first metal layers 141 disposed on a plurality of first pads 131 and a plurality of second metal layers 142 disposed on a plurality of second pads 132. In addition, a lower surface of each of the plurality of first metal layers 141 has a convex part 141B corresponding to the concave-convex part 111T provided on the upper surface of the second layer 111-2 of the first insulating layer 111. In addition, a lower surface of each of the plurality of second metal layers 142 has a convex part 142B corresponding to the concave-convex part 111T provided on the upper surface of the second layer 111-2 of the first insulating layer 111. Through this, the embodiment can increase a contact area between the metal layer 140 and the insulating layer 110, thereby improving the adhesion between the metal layer 140 and the insulating layer 110. Furthermore, the embodiment can minimize a height deviation of the upper surface of each of the plurality of first metal layers 141 and the plurality of second metal layers 142 by allowing the metal layer 140 to come into contact with the second layer 111-2 of the first insulating layer 111, thereby allowing the semiconductor device to be stably mounted. In addition, the embodiment can prevent the penetration of an intermetallic compound between the bonding part 310 and the pad part 130 by improving the adhesion between each of the plurality of first metal layers 141 and the plurality of second metal layers 142 and the insulating layer 110, thereby further improving the physical reliability and/or electrical reliability of the semiconductor package.

The plurality of first metal layers 141 and the plurality of second metal layers 142 can be bonding portions where a bonding part 310, such as solder for bonding with the semiconductor device, is disposed.

At this time, the plurality of first metal layers 141 and the plurality of second metal layers 142 include a different metal material from the first pad 131 and the second pad 132. For example, the plurality of first metal layers 141 and the plurality of second metal layers 142 may include a metal material that prevents the intermetallic compound from penetrating in a direction toward the first pad 131 and the second pad 132.

For example, the plurality of first metal layers 141 and the plurality of second metal layers 142 may include nickel. In addition, when the plurality of first metal layers 141 and the plurality of second metal layers 142 include nickel, the adhesion between the pad part 130 and the bonding part 310 can be improved, and further, the diffusion of the intermetallic compound can be prevented. For example, the intermetallic compound has a problem of poor mechanical and electrical reliability. In particular, when the pad part 130 includes copper, mechanical reliability problems such as crack problems and/or electrical characteristic degradation caused by intermetallic compounds and/or electrical reliability problems may be further aggravated. At this time, when a plurality of first metal layers 141 and a plurality of second metal layers 142 include nickel and are provided to surround exposed surfaces of each of the first pads 131 and the second pads 132, diffusion of a bonding part 310 such as solder can be prevented, thereby preventing the formation of intermetallic compounds, thereby improving the electrical and mechanical reliability of the semiconductor package. Furthermore, the plurality of first metal layers 141 and the plurality of second metal layers 142 come into contact with the second layer 111-2 of the first insulating layer 111 whose flatness is improved compared to a prior art, thereby further improving the adhesion therebetween, and thus further preventing the penetration of intermetallic compounds. At this time, the plurality of first metal layers 141 and the plurality of second metal layers 142 may include a metal other than nickel. For example, the plurality of first metal layers 141 and the plurality of second metal layers 142 may include gold and/or palladium.

FIG. 4 is a cross-sectional view showing a semiconductor package according to a second embodiment.

Referring to FIG. 4, the semiconductor package may have different shapes of the pad part 130 and the metal layer 140 compared to the semiconductor package of FIG. 1. Therefore, same reference numerals are given to same configurations as the semiconductor package of FIG. 1 below, and a detailed description thereof will be omitted.

Referring to FIG. 4, the pad part 130A includes a side surface with a tapered slope.

For example, the side surface of the pad part 130A includes a portion where the slope changes. Here, a portion where the slope changes means not only that a direction of the slope changes, but also that a size of the slope changes.

That is, the pad part 130A overlaps the first layer 111-1 of the first insulating layer 111 along the horizontal direction, and accordingly includes a first portion 130A-1 overlapping the reinforcing member 111F along the horizontal direction. In addition, the pad part 130A overlaps the second layer 111-2 of the first insulating layer 111 along the horizontal direction, and accordingly includes a second portion 130A-2 that does not overlap the reinforcing member 111F along the horizontal direction. In addition, the second portion 130A-2 of the pad part 130A includes a tapered slope side surface whose width changes along the vertical direction.

A side surface of the second portion 130A-2 of the pad part 130A may include a first slope 130A-2S1 whose width is gradually increased toward the lower surface of the pad part 130A and is adjacent to the upper surface 130A-2T of the pad part 130A. In addition, the side surface of the second portion 130A-2 of the pad part 130A includes a second slope 130A-2S2 that is different from the first slope 130A-2S1. The second slope 130A-2S2 may be perpendicular to the upper surface 130A-2T or the lower surface of the pad part 130A, but is not limited thereto. In addition, the side surface of the first portion 130A-1 of the pad part 130A has a same slope 130A-1S as the second slope 130A-2S2 of the second portion 130A-2. That is, the pad part 130A includes the first slope 130A-2S1 and the second slope 130A-2S2. At this time, in FIG. 4, the second portion 130A-2 of the pad part 130A includes the first slope 130A-2S1 and the second slope 130A-2S2, and the first insulating layer 111 includes the slope 130A-1S corresponding to the second slope 130A-2S2, but it is not limited thereto. For example, the side surface of the second portion 130A-2 of the pad part 130A may include only the first slope 130A-2S1 as a whole, and the first portion 130A-1 of the pad part 130A may include each of the first slope and the second slope. Alternatively, the side surface of the second portion 130A-2 of the pad part 130A may include only the first slope as a whole, and the first portion 130A-1 may include only the second slope as a whole.

An interior angle between the upper surface 130A-2T of the pad part 130A and the first slope 130A-2S1 is an obtuse angle. The interior angle between the upper surface 130A-2T of the pad part 130A and the first slope 130A-2S1 can have a range between 95 degrees and 160 degrees. The interior angle between the upper surface 130A-2T of the pad part 130A and the first slope 130A-2S1 can have a range between 100 degrees and 150 degrees. The interior angle between the upper surface 130A-2T of the pad part 130A and the first slope 130A-2S1 can have a range between 105 degrees and 140 degrees. If the internal angle between the upper surface 130A-2T of the pad part 130A and the first slope 130A-2S1 is less than 95 degrees, the effect of increasing the contact area between the pad part 130A and the metal layer 140A may be insufficient, which may cause a problem in which the metal layer 140A is peeled off from the pad part 130A. For example, the circuit board may expand and/or contract due to thermal stress, which may cause a mechanical reliability problem in which the pad part 130A and the metal layer 140A are peeled off from each other. In addition, if the internal angle between the upper surface 130A-2T of the pad part 130A and the first slope 130A-2S1 exceeds 160 degrees, a difference in the width between the upper surface and the lower surface of the pad part 130A may become large. In addition, as a difference in the width between the upper surface and the lower surface of the pad part 130A increases, the transmission loss of the signal transmitted through the pad part 130A may increase, which may result in a deterioration of the signal transmission characteristics. In addition, as the width of the upper surface and the width of the lower surface of the pad part 130A increase, an area of the upper surface of the pad part 130A may decrease, and accordingly, the semiconductor device may not be stably disposed on the pad part 130A.

In addition, the first slope 130A-2S1 and the second slope 130A-2S2 of the pad part 130A may be provided by a process of flattening the pad part 130A or a preprocessing process before forming the metal layer 140A. Through this, the embodiment can minimize a change in the characteristics of the signal transmitted through the pad part 130A. For example, impedance matching can be performed by adjusting the thickness and/or width of the pad part 130A. At this time, if a plurality of pads of the pad part 130A have different thicknesses and/or heights due to plating deviation, etc., the impedance characteristics may change accordingly, which may cause electrical reliability problems. Therefore, in the embodiment, the pad part 130A includes a first slope 130A-2S1 and a second slope 130A-2S2, thereby improving the adhesion between the pad part 130A and the metal layer 140A, while preventing changes in the electrical characteristics of the pad part 130A. In an embodiment, the pad part 130A includes a first slope 130A-2S1 and a second slope 130A-2S2 by a flattening process or a pretreatment process, thereby improving the flatness of the upper surface of the pad part 130A, or preventing foreign substances from remaining on the upper surface of the pad part 130A, thereby improving the electrical characteristics.

At this time, at least a part of the first slope 130A-2S1 of the pad part 130A does not contact the insulating layer 110. Preferably, at least a part of the first slope 130A-2S1 of the pad part 130A may overlap the second layer 111-2 of the first insulating layer 111 in a horizontal direction without contacting the second layer 111-2.

That is, the pad part 130A is provided in a recess 111R provided in the first insulating layer 111. The recess 111R has a through hole 111R1 penetrating the second layer 111-2 of the first insulating layer 111, and a groove part 111R2 provided in the first layer 111-1. At this time, an inner wall of the through hole 111R1 of the second layer 111-2 and the first slope 130A-2S1 of the pad part 130A may be spaced apart by a predetermined distance along the horizontal direction. For example, a separation portion may be provided between the inner wall of the through hole 111R1 of the second layer 111-2 and the first slope 130A-2S1 of the pad part 130A.

Accordingly, the metal layer 140A can be in contact with the first slope 130A-2S1 of the pad part 130A and the inner wall of the through hole 111R1 of the second layer 111-2. That is, the metal layer 140A can be provided to fill the separation portion. That is, the metal layer 140A is provided to cover the first slope 130A-2S1 of the pad part 130A. The side surface of the metal layer 140A has a slope 140AS corresponding to the first slope 130A-2S1 of the pad part 130A.

Through this, the embodiment can further improve the adhesion between the insulating layer 110, the pad part 130A, and the metal layer 140A, and can improve the electrical reliability and/or mechanical reliability of the semiconductor package accordingly.

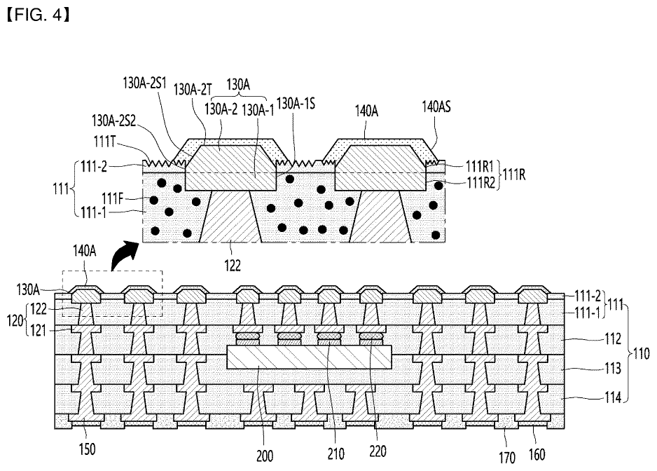

FIG. 5 is a cross-sectional view showing a semiconductor package according to a third embodiment.

Referring to FIG. 5, the semiconductor package may be different from the semiconductor package of FIG. 4 in that it further includes a protective layer 180 disposed on the metal layer 140A. Therefore, the same reference numerals are given to the same configurations as the semiconductor package of FIG. 4 below, and a detailed description thereof will be omitted.

The semiconductor package further includes a protective layer 180 disposed on the insulating layer 110.

The protective layer 180 is disposed on the second layer 111-2 of the first insulating layer 111. In addition, the protective layer 180 is disposed on a metal layer 140A.

The protective layer 180 includes an opening 180R. The opening 180R overlaps the metal layer 140A in a vertical direction. Accordingly, at least a portion of the upper surface of the metal layer 140A is not covered with the protective layer 180. In addition, a portion of the upper surface of the metal layer 140A that is not covered with the protective layer 180 can function as a bump that is electrically coupled to the semiconductor device.

When the protective layer 180 is provided, the embodiment can solve the problem of electrical shorts due to the plurality of adjacent bonding parts being connected to each other in a process of arranging the bonding part 310 on the metal layer 140A, thereby further improving the electrical reliability of the semiconductor package. In addition, the protective layer 180 can be additionally disposed on the second layer 111-2 of the first insulating layer 111 to further facilitate the warpage control of the semiconductor package, thereby improving the physical reliability and/or electrical reliability of the semiconductor package.

The protective layer 180 has a convex part 180B. That is, the protective layer 180 has a convex part 180B that fills the concave-convex part 111T provided on the upper surface of the second layer 111-2 of the first insulating layer 111. Through this, the embodiment can further improve the adhesion between the protective layer 180 and the insulating layer 110, thereby solving the problem of the protective layer 180 being peeled off from the insulating layer 110, and stably protecting at least a part of the metal layer 140A by the protective layer 180. Furthermore, since the protective layer 180 is disposed to cover at least a part of the metal layer 140A, the embodiment can further prevent the intermetallic compound from penetrating into the interface between the insulating layer 110 and the metal layer 140A, thereby further improving the physical reliability and/or mechanical reliability of the semiconductor package.

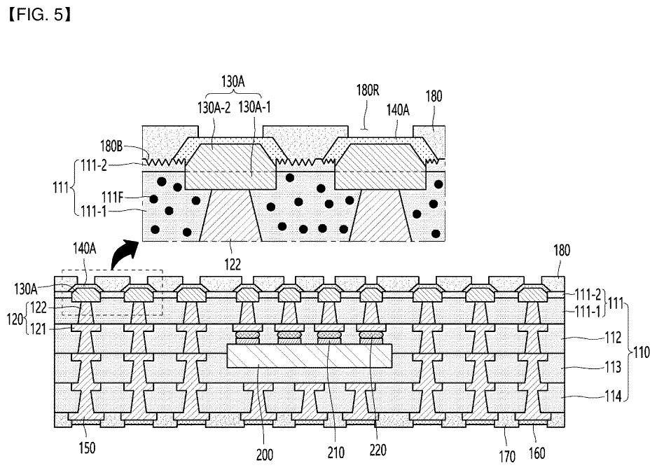

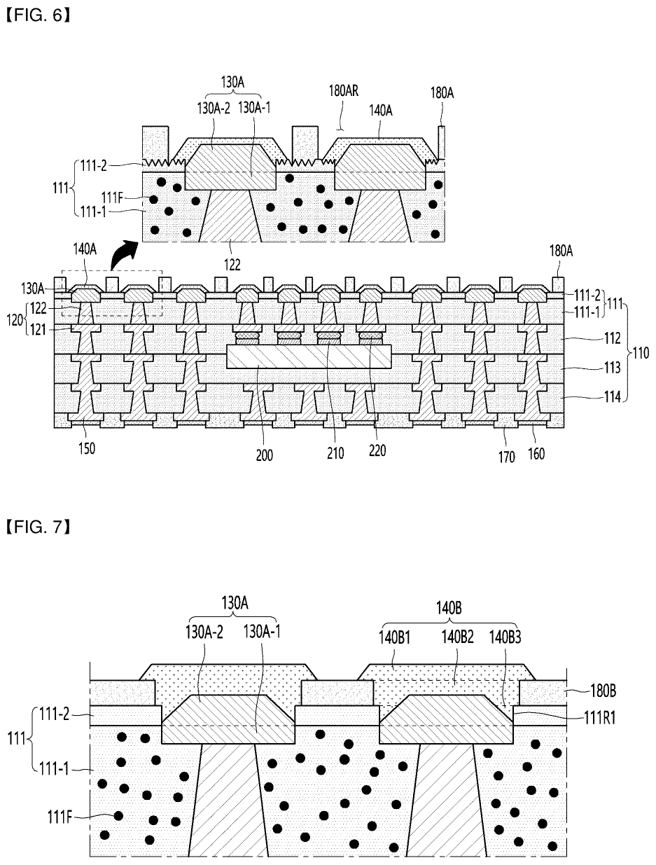

FIG. 6 is a cross-sectional view showing a semiconductor package according to a fourth embodiment.

Referring to FIG. 6, the semiconductor package may be different from the semiconductor package of FIG. 5 in that a width of the opening provided in the protective layer is larger than a width of the metal layer 140A. Therefore, the same reference numerals are given to the same configurations as the semiconductor package of FIG. 5 below, and a detailed description thereof will be omitted.

The semiconductor package further includes a protective layer 180A disposed on the insulating layer 110.

The protective layer 180A is disposed on the second layer 111-2 of the first insulating layer 111. In addition, the protective layer 180A is disposed on the metal layer 140A.

The protective layer 180A has an opening 180AR overlapping the metal layer 140A in the vertical direction. A width of the opening 180AR in the horizontal direction may be larger than a width of the metal layer 140A in the horizontal direction. For example, the metal layer 140A may not be in contact with the protective layer 180A.

Through this, the embodiment can increase a volume of the bonding part 310 disposed on the metal layer 140A, thereby improving the bonding strength with the semiconductor device.

FIG. 7 is a cross-sectional view showing a portion of a region of a semiconductor package according to a fifth embodiment.

Referring to FIG. 7, the semiconductor package may be different from the semiconductor package of FIG. 6 in that the metal layer has a structure in which it protrudes above the protective layer while penetrating the protective layer. Therefore, the same reference numerals are given to the same configuration as the semiconductor package of FIG. 6 below, and a detailed description thereof will be omitted.

The semiconductor package includes a metal layer 140B disposed on the pad part 130A.

At this time, the metal layer 140B may be different from the previous embodiment in that the metal layer 140B is formed after the protective layer 180B is formed. Accordingly, the metal layer 140B can protrude above the protective layer 180B while penetrating through the protective layer 180B.

A width of the opening of the protective layer 180B is larger than a width of the pad part 130A. Accordingly, an inner wall of the opening of the protective layer 180B and an inner wall of the through hole 111R1 provided in the second layer 111-2 of the first insulating layer 111 can have a step.

The metal layer 140B is disposed on the pad part 130A. In addition, the metal layer 140B is disposed on the protective layer 180B. The metal layer 140B can protrude above the protective layer 180B while filling the opening of the protective layer 180B. Therefore, the metal layer 140B can be divided into a plurality of regions along the vertical direction.

The metal layer 140B may include a first portion 140B1 protruding above the protective layer 180B. A width of the first portion 140B1 of the metal layer 140B in the horizontal direction is larger than a width of the opening of the protective layer 180B. Therefore, at least a portion of the first portion 140B1 of the metal layer 140B contacts the upper surface of the protective layer 180B. The side surface of the first portion 140B1 of the metal layer 140B may have a slope that increases in width in a downward direction.

In addition, the metal layer 140B includes a second portion 140B2 penetrating the opening of the protective layer 180B. The second portion 140B2 of the metal layer 140B contacts the inner wall of the opening of the protective layer 180B.

In addition, the metal layer 140B includes a third portion 140B3 that fills a gap between the inner wall of the through hole 111R1 of the second layer 111-2 of the first insulating layer 111 and the first slope 130A-2S1 of the pad part 130A.

Accordingly, the side surface of the metal layer 140B may have a step in the horizontal direction. For example, the side surface of the first to third portions of the metal layer 140B may have a step. Through this, the embodiment may further increase a contact area between the metal layer 140B and the protective layer 180B or the pad part 130A, thereby further improving the adhesion therebetween.

In addition, the metal layer 140B protrudes on the protective layer 180B, thereby improving the alignment between the metal layer 140B and the terminal of the semiconductor device. For example, in the embodiment, when thermal compression bonding is performed to reduce the volume of a connecting member such as solder, a positional alignment between the terminal of the semiconductor device and the metal layer 140B in the thermal compression bonding process can be improved as the metal layer 140B is protruded on the protective layer 180B.

Furthermore, in the embodiment, since the first insulating layer 111 has the first layer 111-1 and the second layer 111-2, a flatness of the upper surface of the protective layer 180B disposed on the second layer 111-2 can be improved, thereby improving the flatness of the metal layer 140B disposed on the protective layer 180B.

FIG. 8 is a cross-sectional view showing a part of a region of a semiconductor package according to a sixth embodiment.

Referring to FIG. 8, the semiconductor package is different from the semiconductor package of FIG. 7 in that the width of the opening of the protective layer is smaller than the width of the pad part. Therefore, in the following, the same reference numerals are given to the same configurations as the semiconductor package of FIG. 7, and a detailed description thereof will be omitted.

The protective layer 180C is disposed on the second layer 111-2 of the first insulating layer 111 and the pad part 130A. At this time, a width of the opening of the protective layer 180C is smaller than a width of the upper surface of the second portion 130A-2 of the pad part 130A. Accordingly, the protective layer 180C may be provided to fill a gap between the inner wall of the through hole 111R1 of the second layer 111-2 of the first insulating layer 111 and the first slope 130A-2S1 of the side surface of the pad part 130A.

The metal layer 140C is disposed on the pad part 130A. In addition, the metal layer 140C is disposed on the protective layer 180C. At this time, the metal layer 140C includes a first portion 140C1 disposed on the protective layer 180C and a second portion 140C2 penetrating the protective layer 180C. At this time, widths of the first portion 140C1 and the second portion 140C2 of the metal layer 140C are smaller than a width of the pad part 130A. Through this, the embodiment can further reduce a width of the metal layer 140C, thereby reducing a pitch between adjacent multiple metal layers. In addition, when the pitch between the adjacent metal layers is maintained to be the same as the previous embodiment, the embodiment can increase a spacing between the adjacent metal layers, thereby solving the electrical short problem in which the multiple metal layers are connected to each other.

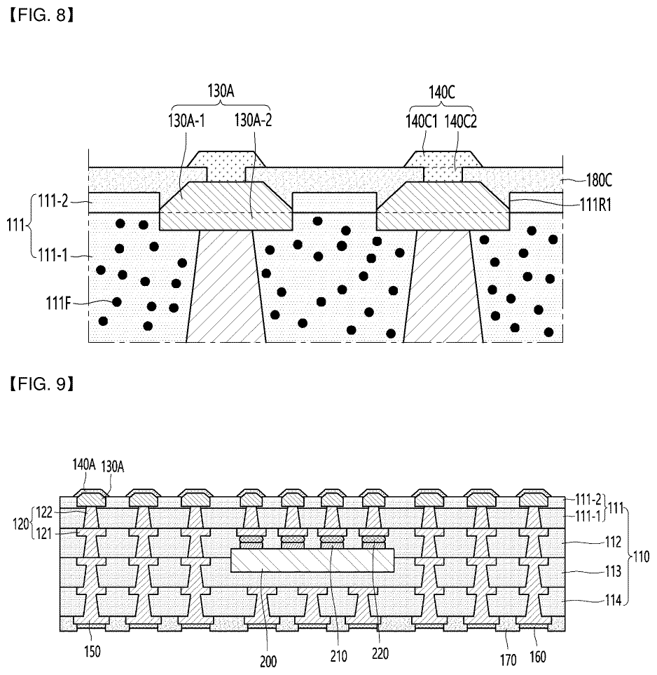

FIG. 9 is a cross-sectional view showing a semiconductor package according to a seventh embodiment.

Referring to FIG. 9, the semiconductor package of the seventh embodiment may have a difference in the thickness of the second layer 111-2 of the first insulating layer 111 compared to the semiconductor package of the second embodiment of FIG. 4.

That is, the semiconductor package of the seventh embodiment has an insulating layer 110. The insulating layer 110 includes a first insulating layer 111 disposed on an uppermost side.

The first insulating layer 111 includes a first layer 111-1 having a reinforcing member and a second layer 111-2 not having a reinforcing member.

At this time, the upper surface of the first layer 111-1 is positioned lower than the lower surface of the pad part 130A. In addition, the lower surface of the second layer 111-2 is positioned lower than the lower surface of the pad part 130A. Accordingly, the pad part 130A may not overlap the reinforcing member of the pad part 130A along the horizontal direction as a whole. For example, the pad part 130A may not overlap the first layer 111-1 of the first insulating layer 111 along the horizontal direction, and may overlap the second layer 111-2 along the horizontal direction. Furthermore, at least a part of the side surface of the second electrode part 122 penetrating the first layer 111-1 may be surrounded by the second layer 111-2 of the first insulating layer 111.

Through this, the embodiment can control the warpage characteristics of the semiconductor package by increasing the thickness of the second layer 111-2 of the first insulating layer 111, thereby solving the problem of the semiconductor package being greatly bent in a specific direction.

The embodiment can improve a flatness of a circuit board and a semiconductor package including the same, and can stably mount a semiconductor device.

Specifically, the circuit board of the embodiment and the semiconductor package including the same include an insulating layer including a filler, a pad part disposed on the insulating layer, and a metal layer disposed on the pad part. In addition, the pad part includes a first portion that overlaps the filler of the insulating layer along a horizontal direction, and a second portion that does not overlap the filler of the insulating layer along the horizontal direction. At this time, the insulating layer includes a first layer having a reinforcing member and a second layer that does not have a reinforcing member. In addition, the first portion of the pad part overlaps the first layer of the insulating layer along the horizontal direction, and the second portion overlaps the second layer of the insulating layer along the horizontal direction. Accordingly, the embodiment can prevent the reinforcing member from being disposed on the second layer, so that a height of an upper surface of the second layer can be uniform as a whole.

In addition, the embodiment can improve the adhesion between the metal layer and the insulating layer disposed on the pad part.

That is, the upper surface of the insulating layer is positioned lower than an upper surface of the pad part. In addition, the upper surface of the insulating layer is positioned higher than a lower surface of the pad part. That is, at least a part of the pad part is embedded in the insulating layer, and at least the remaining part protrudes above the insulating layer. To this end, the embodiment performs a process of reducing a thickness by etching a partial region of the insulating layer while the upper surface of the insulating layer is positioned at a height higher than the upper surface of the pad part.

At this time, if the reinforcing member is provided in the entire region of the insulating layer, a flatness of the upper surface of the insulating layer may be reduced in the process of etching the insulating layer to reduce the thickness. That is, if the process of etching the insulating layer to reduce the thickness while the reinforcing member is provided in the entire region of the insulating layer is performed, the reinforcing member provided in the insulating layer may be exposed to an upper side of the insulating layer. In addition, if the reinforcing member provided in the insulating layer is exposed to the upper side, the adhesion between the insulating layer and the metal layer described later may be reduced. For example, the adhesion between the reinforcing member and the metal layer may be weaker than the adhesion between the resin of the insulating layer and the metal layer. Due to this, the adhesion between the insulating layer and the metal layer may be reduced, and the metal layer may be peeled off from the insulating layer. In addition, when the metal layer comes into contact with the reinforcing member, a loss of electrical signals and/or power transmitted through the metal layer may occur due to the reinforcing member having a relatively high permittivity.

In addition, when a process of etching the insulating layer to reduce the thickness is performed while the reinforcing member is provided in the entire region of the insulating layer, at least some of the reinforcing members provided in the insulating layer may be removed, and thus a concave part, which is a space where the reinforcing member is removed, may be provided on the upper surface of the insulating layer. At this time, the concave part may have a greater depth than other parts of the upper surface of the insulating layer. Due to this, when the concave part is provided on the upper surface of the insulating layer, a problem may occur in which the metal layer does not completely fill the concave part, and thus a void may be provided between the insulating layer and the metal layer. Furthermore, when a concave part having a relatively large depth is provided on the upper surface of the insulating layer, stress acting on the insulating layer may be concentrated on the concave part, which may deteriorate the physical reliability and/or electrical reliability of the semiconductor package.

In contrast, the insulating layer of the embodiment has a first layer and a second layer. In addition, the first layer of the insulating layer has a resin and a reinforcing member, and the second layer does not have a reinforcing member and includes only a resin. Therefore, the embodiment can prevent the reinforcing member from being exposed on the upper surface of the insulating layer after etching, and thus can allow a height of the upper surface of the insulating layer to be uniform.

Therefore, the embodiment can improve the flatness of the circuit board and the semiconductor package including the same. Furthermore, the metal layer disposed on the pad part does not come into contact with the reinforcing member, and thus the embodiment can improve the electrical characteristics of the metal layer while enhancing the adhesion between the metal layer and the insulating layer.

Furthermore, the embodiment can prevent stress from being concentrated at a specific location on the upper surface of the insulating layer by ensuring that the upper surface of the insulating layer has a uniform height, and further, can evenly distribute the stress to the entire region, thereby improving the physical reliability and electrical reliability of the semiconductor package.

In addition, the embodiment can prevent a bonding part disposed on the metal layer from penetrating into a gap between the metal layer and the insulating layer by improving the adhesion between the metal layer and the insulating layer.

Therefore, the embodiment can suppress the formation of an intermetallic compound (IMC) with poor brittleness between the bonding part and the pad part, thereby improving the physical reliability and electrical reliability of the semiconductor package.

In addition, the embodiment can prevent the semiconductor package from being greatly warped in a specific direction by providing the first layer with the reinforcing member and the second layer without the reinforcing member as the insulating layer, and thus, can stably mount the semiconductor device, and further, can stably operate the semiconductor device.

Specifically, the circuit board and the semiconductor package including the circuit board may be significantly warped in a specific direction. This may occur due to a difference in coefficients of thermal expansion between the insulating layer and the protective layer, a difference in thicknesses of each layer of the insulating layer, a difference in a density of electrode parts provided on a surface of each layer of the insulating layer, a difference in a density of electrode parts provided on a surface of each layer of the insulating layer, and a difference in thicknesses of electrode parts provided on a surface of each layer of the insulating layer. At this time, the embodiment provides a second layer of the insulating layer that does not have a reinforcing member on an uppermost side of a circuit board. The second layer of the insulating layer can have a coefficient of thermal expansion matching function that alleviates a difference in coefficients of thermal expansion between different insulating layers, thereby preventing the circuit board from being significantly warped in a specific direction. For example, the circuit board may be warped downward at both ends in a state where the second layer is not provided on the insulating layer. At this time, the second layer provided on the insulating layer can induce both ends of the circuit board to be warped upward, thereby ultimately allowing the circuit board to maintain a flat state without being warped.

In addition, a concave-convex part is provided on the upper surface of the second layer of the insulating layer. The concave-convex part may be provided on the upper surface of the second layer in a process of etching the second layer of the insulating layer to reduce the thickness of the second layer. At this time, the embodiment forms the concave-convex part by etching the second layer of the insulating layer that does not have the reinforcing member, and accordingly, the reinforcing member may not be exposed through the concave-convex part, and thereby the concave-convex part may have a uniform depth on the upper surface of the second layer. The concave-convex part contacts at least a part of the metal layer disposed on the pad part. Through this, the embodiment can further improve the adhesion between the insulating layer and the metal layer.

At this time, the concave-convex part has a specific curvature. At this time, the curvature of the concave-convex part is different from the curvature of the reinforcing member provided in the first layer of the insulating layer. Here, the different curvature may mean that the reinforcing member is not exposed upwardly through the concave-convex part. Alternatively, the different curvature may mean that the reinforcing member is not removed from the insulating layer during a process of etching the insulating layer to reduce the thickness of the insulating layer, and thus the concave-convex part does not include a portion formed by the removal of the reinforcing member. Through this, the embodiment may improve the physical reliability and/or electrical reliability of the semiconductor package.

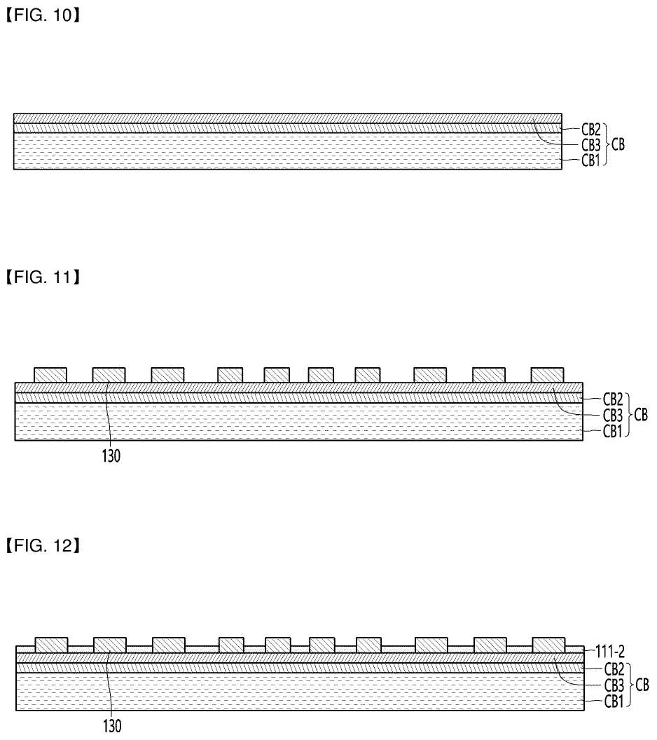

FIGS. 10 to 24 are drawings showing the manufacturing method of the semiconductor package illustrated in FIG. 1 in order of processes.

Referring to FIG. 10, the embodiment prepares an insulating member that serves as a basis for manufacturing a circuit board. The insulating member may be a carrier board CB. For example, the carrier board CB may include a carrier insulating layer CB1 and a carrier metal layer CB2 and CB3. The carrier metal layer CB2 and CB3 may have a two-layer structure. For example, the carrier metal layer CB2 and CB3 may be provided as metal layers including different metal materials. A first carrier metal layer CB2 may be disposed under the carrier insulating layer CB1. The first carrier metal layer CB2 may include a first metal material. The first metal material may include copper. The carrier insulating layer CB1 and the first carrier metal layer CB2 may be a copper clad laminate (CCL). A second carrier metal layer CB3 may be disposed under the first carrier metal layer CB2. The second carrier metal layer CB3 may include a second metal material different from the first metal material. The second metal material may include nickel. For example, the second carrier metal layer CB2 may be formed of a metal material that is not etched by an etchant used to etch the first metal material. Through this, the embodiment can prevent the pad part 130 from being etched in a seed layer etching process included in a manufacturing process of the circuit board. Through this, the embodiment can minimize a height difference between the plurality of first pads and the plurality of second pads of the pad part 130. Although FIG. 10 illustrates that the first carrier metal layer CB2 and the second carrier metal layer CB3 are disposed on one surface of the carrier insulating layer CB1, the embodiment is not limited thereto. For example, a first carrier metal layer CB2 and a second carrier metal layer CB3 may be disposed on both sides of the carrier insulating layer CB1, respectively. In this case, a process of manufacturing multiple circuit boards simultaneously on both sides of the carrier insulating layer CB1 may be performed.

Referring to FIG. 11, the embodiment may perform a process of forming a pad part 130 on the second carrier metal layer CB3. The pad part 130 may be formed by performing electrolytic plating on the second carrier metal layer CB3 as a seed layer.

Referring to FIG. 12, the embodiment may perform a process of laminating a second layer 111-2 of the first insulating layer 111 that covers a portion of the pad part 130 on the second carrier metal layer CB3. The second layer 111-2 does not have a reinforcing member. At this time, after the second layer 111-2 is disposed to entirely cover the pad part 130, a process of etching the second layer to reduce the thickness can be performed so as to cover a part of the side surface of the pad part 130.

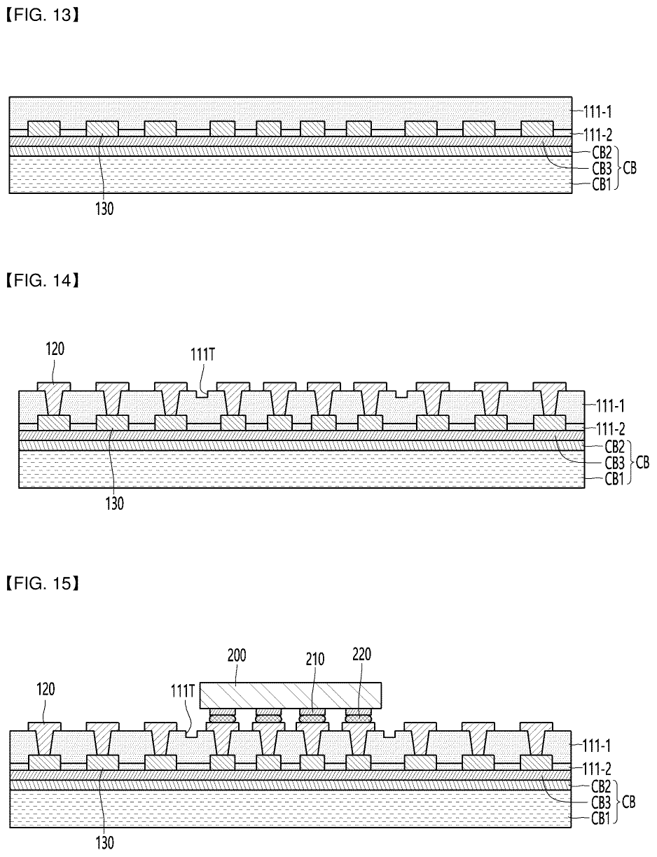

Next, referring to FIG. 13, the embodiment may perform a process of laminating the first layer 111-1 of the first insulating layer 111 on the second layer 111-2. At this time, although it is illustrated that the first layer 111-1 and the second layer 111-2 are laminated separately, the embodiment is not limited thereto. For example, if the first layer 111-1 and the second layer 111-2 are provided as a single layer, the processes of FIG. 12 and FIG. 13 may be performed at once.

Next, referring to FIG. 14, the embodiment may perform a process of forming the electrode part 120 on the first insulating layer 111. At this time, the embodiment can form a concave part 111T on the surface of the first layer 111-1 of the first insulating layer 111 when forming the electrode part 120. At this time, the concave part 111T can be provided to surround an electrode part that vertically overlaps the connection member 200 among the electrode parts.

Next, referring to FIG. 15, the embodiment can perform a process of arranging a bonding member 220 on the electrode part using the concave part 111T as an alignment pit and a process of attaching the connection member 200.

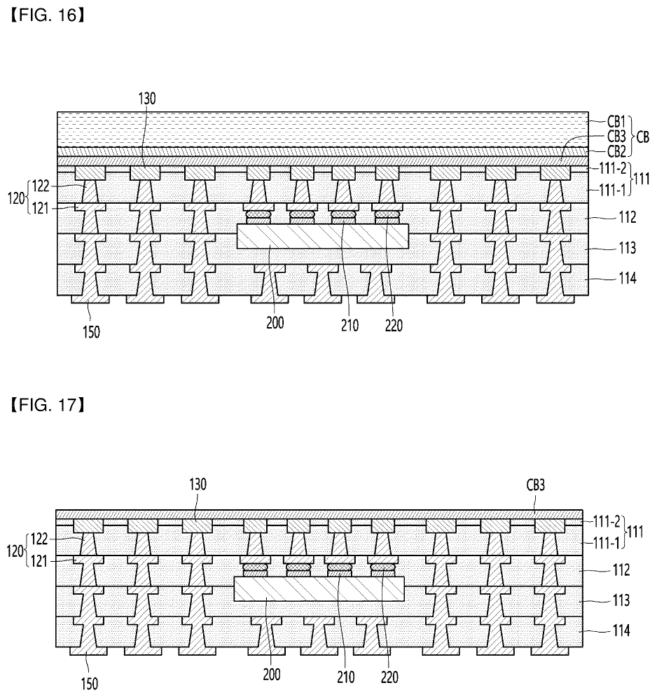

Next, referring to FIG. 16, the embodiment can manufacture a multilayer substrate by repeatedly performing the insulating layer lamination process and the electrode part formation process.

Next, referring to FIG. 17, the embodiment can perform a process of removing the carrier board CB. To this end, the embodiment can perform a process of removing the carrier insulating layer CB1. Thereafter, the embodiment may perform a process of removing the first carrier metal layer CB2. At this time, the second carrier metal layer CB3 includes a different metal material from the first carrier metal layer CB2, and thus may not be removed in the process of removing the first carrier metal layer CB2.

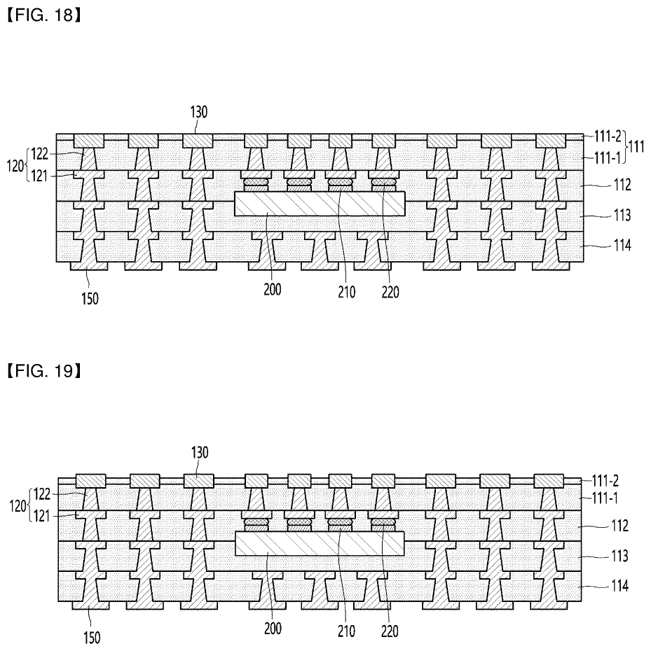

Next, referring to FIG. 18, the embodiment may perform a process of removing the second carrier metal layer CB3 by etching. At this time, the second carrier metal layer CB3 includes a different metal material from the pad part 130, and thus may not be removed in the process of removing the second carrier metal layer CB3.

Next, referring to FIG. 19, the embodiment may perform a process of removing a portion of the second layer 111-2 of the first insulating layer 111 by etching to thin the thickness of the second layer 111-2. Accordingly, the upper surface of the second layer 111-2 of the first insulating layer 111 may be positioned lower than the upper surface of the pad part 130. In addition, the second layer 111-2 is not provided with a reinforcing member, and accordingly, the pad part 130 includes a region that overlaps the second layer 111-2 along the horizontal direction but does not overlap with the reinforcing member along the horizontal direction.

In this way, the embodiment may form a first insulating layer 111 that includes a first layer 111-1 provided with a reinforcing member and a second layer 111-2 that does not have a reinforcing member while being positioned lower than the upper surface of the pad part 130.

At this time, in FIGS. 10 to 19, a substrate manufacturing process was performed in a state where the second layer 111-2 of the first insulating layer 111 was preferentially laminated, but is not limited thereto.

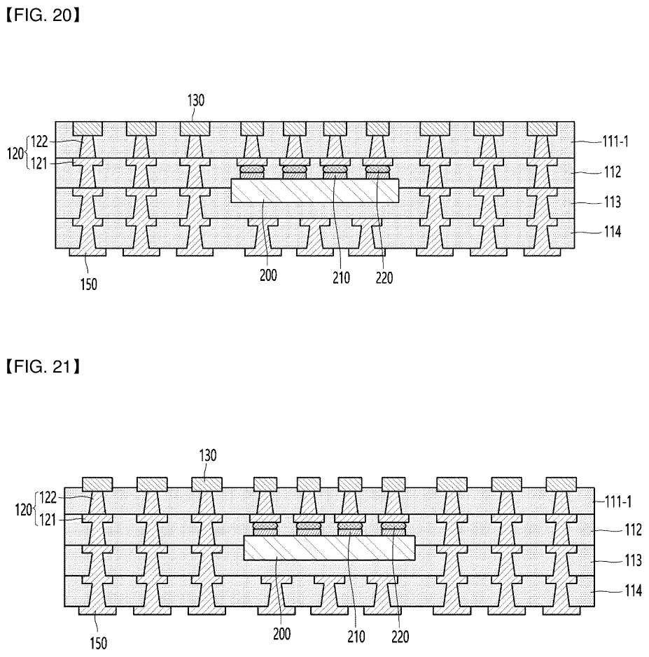

For example, the embodiment may omit a process of laminating the second layer 111-2 of the first insulating layer 111 of FIG. 12 and proceed directly with the process of laminating the first layer 111-1. In this case, as illustrated in FIG. 20, after the carrier board is removed, the first layer 111-1 of the first insulating layer 111 may be provided to entirely cover a side surface of the pad part 130.

Next, referring to FIG. 21, the embodiment may proceed with a process of removing the first layer 111-1 of the first insulating layer 111 by etching to thin the thickness of the first layer. Accordingly, the first layer 111-1 of the first insulating layer 111 is positioned lower than the upper surface of the pad part 130.

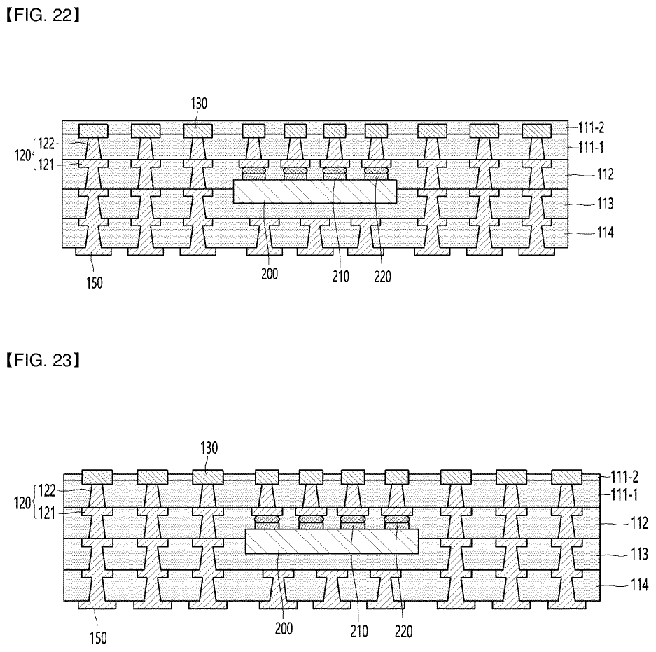

Thereafter, referring to FIG. 22, the embodiment performs a process of laminating a second layer 111-2 on the first layer 111-1 of the first insulating layer 111. At this time, the second layer 111-2 may be provided to entirely cover the upper surface of the pad part 130.

Next, referring to FIG. 23, the embodiment may perform a process of removing the second layer 111-2 by etching to thin the thickness of the second layer. Accordingly, the upper surface of the second layer 111-2 may be positioned lower than the upper surface of the pad part 130.

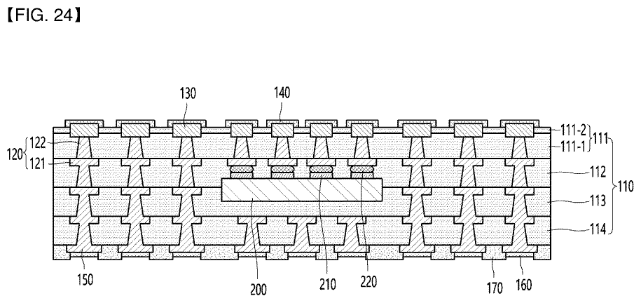

Next, referring to FIG. 24, the embodiment may perform a process of forming a metal layer 140 on the pad part 130. In addition, the embodiment can perform a process of forming a protective layer 170 under the fourth insulating layer 114 and a process of forming a lower metal layer 160 under the lower pad part 150.

On the other hand, when the circuit board having the above-described characteristics of the invention is used in an IT device or home appliance such as a smart phone, a server computer, a TV, and the like, functions such as signal transmission or power supply can be stably performed. For example, when a circuit board having the features of the present invention performs a semiconductor package function, the circuit board can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. A circuit board comprising:
a build-up insulating layer including a plurality of insulating layers laminated along a vertical direction;
a pad part disposed on the build-up insulating layer; and
a metal layer disposed on the pad part,
wherein the build-up insulating layer includes an upper insulating laver disposed closest to the pad part and including a plurality of fillers,
wherein the upper insulating laver includes a first region including the plurality of fillers, and a second region provided on the first region.
wherein the pad part includes a first portion overlapping the first region along a horizontal direction, and a second portion overlapping the second region along the horizontal direction and
wherein a number of fillers overlapping the second portion of the pad part is smaller than a number of fillers overlapping the first portion of the pad part.

2. The circuit board of claim 1, wherein a resin of the first region of the upper insulating layer and a resin of the second region include a same insulating material.

3. The circuit board of claim 1, wherein a resin of the first region of the upper insulating layer and a resin of the second region include different insulating materials.

4. The circuit board of claim 1, wherein the filler includes a first filler provided in the first region of the upper insulating layer, and a second filler provided in the second region of the upper insulating laver, and
wherein a number of second Ellers overlapping the second portion of the pad part is smaller than a number of first fillers overlapping the first portion of the pad part.

5. The circuit board of claim 4, wherein a diameter of the first filler is same as a diameter of the second filler.

6. The circuit board of claim 4, wherein a content of the first filler in the first region of the upper insulating layer is greater than a content of the second filler in the second region.

7. The circuit board of claim 4, wherein a diameter of the second filler is smaller than a diameter of the first filler.

8. The circuit board of claim 1, wherein the first region of the upper insulating laver is a filler region where the plurality of fillers are disposed, and
wherein the second region of the upper insulating laver is a non-filler region where the filler is not disposed.

9. The circuit board of claim 1, wherein the upper insulating laver has a recess that is concave from an upper surface of the upper insulating layer toward a lower surface of the upper insulating laver, and
wherein the pad part is disposed in-the recess.

10. The circuit board of claim 9, wherein the recess has a through hole penetrating the second region of the upper insulating layer, and wherein the pad part is disposed in the through hole.

11. The circuit board of claim 10, wherein the recess has a groove part connected to the through hole and provided on an upper surface of the first region of the upper insulating layer, and
wherein the pad part is disposed in the through hole and the groove part.

12. The circuit board of claim 1, wherein the pad part further includes a third portion positioned on the second portion and protruding on the upper insulating layer without overlapping the upper insulating layer along the horizontal direction.

13. The circuit board of claim 1, wherein an upper surface of the second region of the upper insulating layer is provided with a concave-convex part, and
wherein the metal layer has a convex part corresponding to the concave-convex part.

14. The circuit board of claim 13, wherein a curvature of the concave-convex part is different from a curvature of the filler.

15. The circuit board of claim 1, further comprising:
a protective layer disposed on the metal layer, and
wherein the second portion of the pad part includes a first part overlapped with the second region of the upper insulating layer along the horizontal direction, and a second part provided on the first part and overlapped with the protective layer along the horizontal direction.

16. The circuit board of claim 15, wherein the protective layer has an opening overlapping the metal layer in the vertical direction and penetrating an upper surface and a lower surface of the protective layer, and
wherein a width of the opening in the horizontal direction is smaller than a width of at least one of the pad part and the metal layer in the horizontal direction.

17. The circuit board of claim 11, the second portion of the pad part includes a slope whose width increases toward the first portion.

18. The circuit board of claim 17, wherein a separation portion is provided between the slope of the second portion and an inner wall of the through hole of the second region of the upper insulating layer, and
wherein the metal layer is disposed in the separation portion and contacts the slope of the second portion and the inner wall of the through hole of the second region.

19. The circuit board of claim 1, wherein the build-up insulating layer includes a plurality of lower insulating layers disposed under the upper insulating layer, and wherein each of the lower insulating layers does not have the second region.

20. The circuit board of claim 1, further comprising:
a connection member embedded in the build-up insulating layer and including a connection pad electrically connected to the pad part.
